(19) United States
(12) Patent Application Publication
(10) Pub. No.: US 2008/0320375 A1
(43) Pub. Date: Dec. 25, 2008

(54) DATA TRANSMITTING APPARATUS AND DATA RECEIVING APPARATUS

(75) Inventors: Kiyohide Hori, Osaka (JP); Hiroshi Benno, Osaka (JP); Takashi Ide, Nara (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 12/143,114

(22) Filed: Jun. 20, 2008

(30) Foreign Application Priority Data
Jun. 22, 2007 (JP) 2007-164959

(51) Int. Cl. H03M 13/09; G06F 11/10

(52) U.S. Cl. 714/807; 714/E11.032

(57) ABSTRACT

To provide a data transmitting apparatus and the like capable of enhancing error detection accuracy without increasing a bandwidth unnecessarily used for the error detection performed on encrypted data and minimizing deterioration in sound quality of the data by effectively reducing noises in the transmission of the data through networks for cars and the like even though the data transmitting apparatus has been simply structured. The present invention makes it possible to perform error detection on audio data according to the sizes of encrypted blocks or packets using simple error check codes embedded in the audio data, or to perform error detection using a variation sequence of attribute information to be transmitted together with the audio data. In this case, output of the sound resulting from the audio data having an error is stopped.

### BACKGROUND OF THE INVENTION

(1) Field of the Invention

The present invention relates to data transmission techniques in networks used for cars, and in particular to a technique for reducing errors in transmitting encrypted data using the networks.

(2) Description of the Related Art

In the Media Oriented Systems Transport (MOST), which is one of the conventional network schemes used for cars, no error detection using error check codes is performed in transmitting a media data stream. This is because transmission paths have low error rates and relatively high reliability, and because the scheme is intended for data to be transmitted such as music data which do not cause any fatal problem even when the data is damaged.

However, there has been a need to detect errors in transmitting media data by applying the MOST scheme. This is because, in the case where a transmission error of 1 bit occurs in encrypted and transmitted media data, data obtained by decoding the encrypted data is damaged widely and in a manner unrelated to the original data. For example, in the case where music data is damaged, noises louder and longer than those in the original music data are generated. This problem needs to be prevented. In particular, loud noises from a speaker connected to a device used for cars may cause a fatal problem of triggering a traffic accident by affecting a driver.

In addition, in the MOST scheme, a processing for switching encryption keys on a packet-by-packet basis is performed. Each of packets includes several encrypted blocks and packet information for controlling the packet. For this reason, in the case where important data included in the packet information of a packet is damaged due to a transmission error, the whole packet is damaged, causing a more serious noise problem. Such important data includes coding scheme information necessary for performing switching control of encrypted keys.

An example of the conventional techniques for solving the problem includes a digital watermarking technology for embedding other data such as error check codes and copyright protection information into the original music data while suppressing deterioration in the quality of the original music data by utilizing the characteristics of the music data (refer to Patent Reference 1: Japanese Unexamined Patent Application Publication No. 2000-82963).

Another example is a technique for detecting errors by rounding down the least significant bit of each quantized frame data of music data and adding other data instead of the rounded down data. Another example is a method for reducing the necessary bandwidth by compressing the data and inserting error check codes in the newly-available data area (refer to Patent Reference 2: Japanese Unexamined Patent Application Publication No. 3-147427).

However, the above-described conventional techniques are not suffice to solve the problem. This will be described below.

FIG. 25 is a diagram showing how encryption is performed, in a conventional art, on blocks including several frames. In addition, FIG. 26 is a diagram for illustrating a problem that occurs, in the conventional art, in encrypting and decrypting blocks including several frames.

Each of blocks 240 in FIG. 25 is structured with two pairs of a left-side frame L121 and a right-side frame R122 in FIGS. 2A and 2B. A block 250 is obtained by coding the block 240. It should be noted that the least significant bit (LSB) 123 in each frame in FIG. 25 is a bit used for error check.

Coded blocks 260 in FIG. 26 are the same as the coded blocks 250 in FIG. 25 except that the coded blocks 260 have been partly damaged (in other words, the coded blocks 260 include damaged portions of data 251) due to transmission errors occurred on a transmission path. Decoded blocks 270 in FIG. 26 are blocks obtained by decoding the coded blocks 260 received by a receiving-side apparatus through the transmission path.

The data of the decoded blocks 270 are different from the original data of the coded blocks 240, due to the damage caused on the transmission path. Especially in the case where the coding scheme entails encryption of the data, even damage to 1-bit data of a block affects the whole block in the decoding, and thus the data of the decrypted block 270 is to be significantly different from the original data.

Next, the block 270 is subjected to error detection performed on a frame-by-frame basis. At this time, the data of all the frames in the block 270 are different from those of the original frames. However, even abnormal frames having an error may be judged to be normal when the parities of the respective frames are checked although these frames are different from the corresponding original frames. This is because a parity shows the number of bits of “1” in data and thus it is impossible to detect an error if, for example, 2-bit data is deformed.

For this, even in the case where a mute processing is performed according to a result of error detection performed on a frame-by-frame basis, noises resulting from abnormal frames erroneously judged to be normal are outputted through a speaker.

Next, a case where packet information includes a transmission error is described (refer to FIG. 23A described later).

In the case where the packet information of a transmitted packet is damaged, it is impossible to detect the position of the packet and extract the coding scheme normally. In this case, since the packet cannot be decoded normally, the decoded packet has data significantly different from that of the original packet as in the case of the block 270 in FIG. 26. Accordingly, it is impossible to make a normal error judgment, and thus noises may be outputted from a speaker. At this time, since the data throughout the packet is damaged, noises affect a wider portion of the data compared with the case where data other than the packet information (here, audio data) is damaged.

In the case where error check codes which are embedded in music data are judged on a frame-by-frame basis using flags such as parity bits requiring only a small amount of calculation, it is highly likely that errors occur in encrypted data to be decrypted. When encypted data having an error is decrypted and subjected to an error check, it is highly likely that the data is erroneously recognized as normal data in the error check although the data is significantly damaged.

In general, error check codes such as CRC represented in several bytes require a large amount of calculation and high processinging performance. Therefore, a costly high-speed CPU and large circuit are necessary for real-time processing. Since such error check codes require a number of bits, there is a need to calculate error check codes of a wide range of data and insert them into the data in order to suppress deterioration in sound quality. These error check codes occupy a large portion of a memory.

In an approach for embedding error check codes in music data and detecting errors, and in a method for compressing music data and inserting error check codes such as CRCs in the newly-available bandwidth, the original music data is processed into different data having a deteriorated sound quality.

Unlike the case of media data, it is impossible to perform error check on the data (such as packet information) other than media data by replacing some portions of original data with error check codes.

In general, in a processing of stopping music when a first error occurs and re-starting the music after a predetermined period of time elapses from when a normal state returns, noises may be generated if a second error occurs immediately after the first error. However, stronger error detection for reducing noises results in deterioration in services. For example, even intact data is discarded.

The present invention has been made to solve the above-described problems, and has an object to provide a data transmitting apparatus having a simple structure which makes it possible to enhance error detection accuracy without increasing a bandwidth unnecessarily used for error detection and reduce noises by minimizing deterioration in sound quality.

### SUMMARY OF THE INVENTION

In order to solve the above problem, the data transmitting apparatus according to the present invention is structured to include: at least one unit of transmission data, and transmits the coded unit blocks to a transmission path; and a receiving unit which receives the coded unit blocks from the transmitting unit through the transmission path, the unit block being a minimum amount of data which is coded at a time, and the unit of transmission data being a minimum amount of data which is transmitted at a time, wherein the receiving unit includes: a decoding unit configured to decode the coded unit blocks, and extract the units of transmission data of the respective coded unit blocks; a check information detecting unit configured to judge whether or not each of the extracted units of transmission data has an error, based on check information usable for error detection, and identify, in the case where a unit of transmission data is judged as having an error, an error unit block including the unit of transmission data judged as having the error; and an error control unit configured to perform an error processing on the whole identified error unit block.

This makes it possible to achieve a data transmitting apparatus capable of enhancing error detection accuracy without increasing a bandwidth unnecessarily used for error detection and reducing noises by minimizing deterioration in sound quality even though the data transmitting apparatus has been simply structured.

The transmitting apparatus according to the present invention codes unit blocks each of which includes at least one unit of transmission data, and transmits the coded unit blocks to a transmission path, and the transmitting apparatus includes: a check information inserting unit configured to insert check information usable for error detection in the unit block, and a coding unit configured to code the unit block in which the check information is inserted, and transmit the coded unit block to the transmission path. The receiving apparatus according to the present invention receives the coded unit blocks from the transmitting apparatus through the tranmisssion path, and the receiving apparatus includes: a decoding unit configured to decode the coded unit blocks, and extract the units of transmission data of the respective decoded unit blocks; a check information detecting unit configured to judge whether or not each of the extracted units of transmission data has an error, based on check information usable for error detection, and identify, in the case where a unit of trasnsmission data is judged as data having an error, an error unit block including the unit of transmission data judged as having the error; and an error control unit congifured to perform an error processing on the whole identified error unit block.

This makes it possible to achieve a transmitting apparatus and a receiving apparatus capable of enhancing error detection accuracy without increasing a bandwidth unnecessarily used for error detection and reducing noises by minimizing deterioration in sound quality even though the transmitting apparatus and the receiving apparatus have been simply structured.

A data transmission system comprising: a transmitting apparatus which codes unit blocks each of which includes at least one unit of transmission data, and transmits the coded unit blocks to a transmission path; and a receiving apparatus which receives the coded unit blocks from the tranmitting apparatus through the transmission path, the unit block being a minimum amount of data which is coded at a time, and the unit of transmission data being a minimum amount of data which is transmitted at a time, wherein the tranmitting apparatus includes: a check information inserting unit configured to insert check information usable for error detection in the unit block, and a coding unit configured to code the unit block in which the check information is inserted, and transmit the coded unit block to the transmission path, and wherein the receiving apparatus includes: a decoding unit configured to decode the coded unit blocks, and extract the units of transmission data of the respective decoded unit blocks; a check information detecting unit configured to judge whether or not each of the extracted units of transmission data has an error, based on check information usable for error detection, and identify, in the case where a unit of transmission data is judged as having an error, an error unit block including the unit of transmission data judged as having the error; and an error control unit configured to perform an error processing on the whole identified error unit block.

This makes it possible to achieve a data transmission system capable of enhancing error detection accuracy without increasing a bandwidth unnecessarily used for error detection and reducing noises by minimizing deterioration in sound quality even though the data transmission system has been simply structured.

It should be noted that the present invention can be implemented as a data transmission system having the steps corresponding to the unique structural elements in the above-described data transmitting apparatus. Further, the present invention can be implemented as a transmitting method and a receiving method having the steps corresponding to the unique structural elements in the above-described transmitting apparatus and receiving apparatus. Furthermore, the present invention can be implemented as a program causing a computer to execute these steps of the above-described methods. As a matter of course, the program can be distributed widely through recording media such as DVDs and transmission media such as the Internet.

The present invention having a simple structure makes it possible to enhance error detection accuracy without increasing a bandwidth unnecessarily used for error detection of coded data without deteriorating or while minimizing deterioration in sound quality in the transmission of the coded data through networks for cars, and thereby reducing noises effectively.

### FURTHER INFORMATION ABOUT TECHNICAL BACKGROUND TO THIS APPLICATION

The disclosure of Japanese Patent Application No. 2007-164959 filed on Jun. 22, 2007 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a block diagram of a functional structure of a data transmitting apparatus in a first embodiment of the present invention.

FIG. 2A is a diagram showing an example format of media data according to the present invention. FIG. 2B is a diagram showing an example of inserting error check codes into the media data according to the present invention.

FIG. 3 is a diagram showing an example of a hierarchical structure of media data according to the present invention.

FIG. 4 is a flowchart of processes performed by a check code detecting unit according to the first embodiment.

FIG. 5 is a block diagram of a functional structure of a data transmitting apparatus in a second embodiment of the present invention.

FIG. 6 is a flowchart of processes performed by a check code detecting unit according to the second embodiment.

FIG. 7 is a flowchart of processes performed by a check code detecting unit according to the second embodiment.

FIG. 8 is a block diagram of a functional structure of a data transmitting apparatus in a third embodiment of the present invention.

FIG. 9 shows an example of a state transition diagram used by an attribute information analyzing unit according to the third embodiment.

FIG. 10 shows an example of a state transition diagram used by the attribute information analyzing unit according to the third embodiment.

FIGS. 11A and 11B are diagrams each of which shows examples of several packets and the attribute information of the same.

FIG. 12 is a block diagram of a functional structure of a data transmitting apparatus in a fourth embodiment of the present invention.

FIG. 13 is a flowchart of processes performed by an attribute information converting unit according to the fourth embodiment.

FIG. 14 shows an example of a state transition diagram used by an attribute information analyzing unit according to the fourth embodiment.

FIGS. 15A to 15C are diagrams each of which shows examples of packets and the attribute information of the same according to the fourth embodiment.

FIG. 16 is a flowchart of processes performed by an attribute information converting unit according to the fourth embodiment.

FIG. 17 is a flowchart of processes performed by an attribute information converting unit according to the fourth embodiment.

FIGS. 18A to 18C are diagrams each of which shows examples of packets and the attribute information of the same according to the fourth embodiment.

FIG. 19 is a block diagram of a functional structure of a data transmitting apparatus in a fifth embodiment of the present invention.

FIG. 20 is a flowchart of conventional processes performed by an error control unit.

FIGS. 21A and 21B are diagrams each of which shows the relationship between the data states and data output statuses according to the fifth embodiment.

FIG. 22 is a flowchart of processes performed by an error control unit according to the fifth embodiment.

FIGS. 23A to 23D are diagrams each of which illustrates to-be-transmitted packets assigned with packet information according to the fifth embodiment.

FIG. 24 is a flowchart of processes performed by a packet information extracting unit according to the fifth embodiment.

FIG. 25 is a diagram illustrating how blocks including several frames are encrypted in the conventional technique.

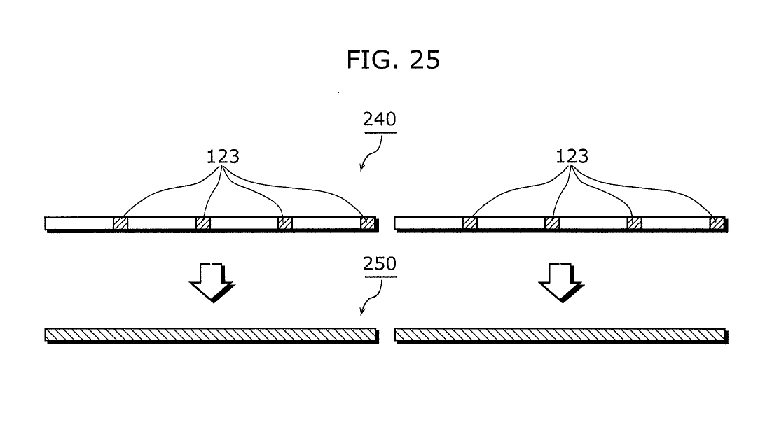

FIG. 26 is a diagram for illustrating a problem that occurs in the encryption and decryption of blocks including several frames in the conventional technique.

### DESCRIPTION OF THE PREFERRED EMBODIMENTS

Embodiments according to the present invention will be described below in detail with reference to the drawings. It should be noted that, although only some exemplary embodiments of the present invention will be described below with reference to the attached drawings, those skilled in the art will readily appreciate that many modifications are possible in the exemplary embodiments without materially departing from the novel teachings and advantages of this invention. Accordingly, all such modifications are intended to be included within the scope of this invention.

### First Embodiment

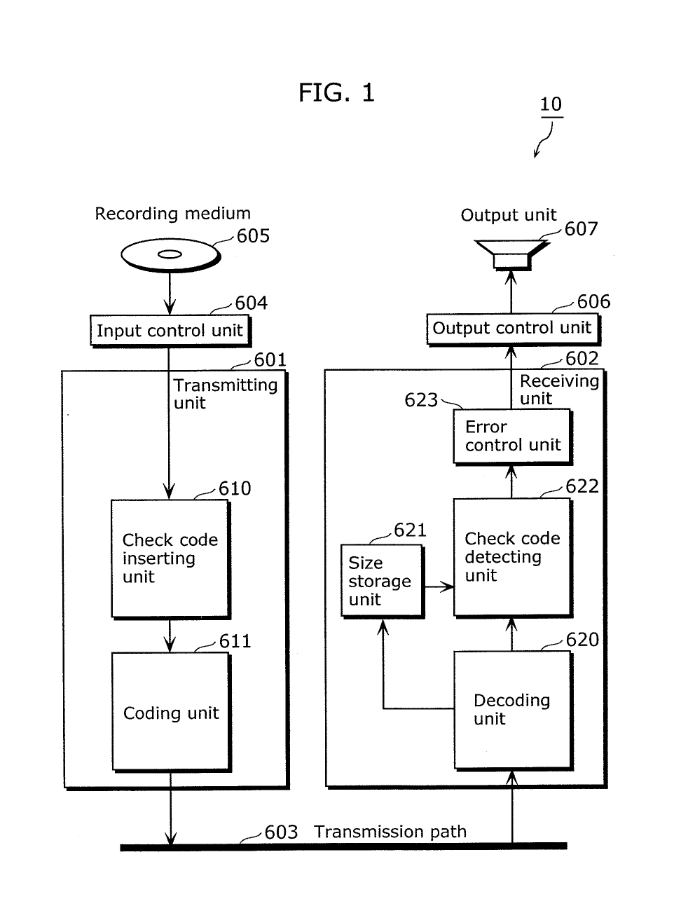

FIG. 1 is a block diagram of a functional structure of a data transmitting apparatus 10 in this embodiment.

The data transmitting apparatus 10 transmits, for example, contents including media data through a transmission path 603 (in other words, transmits media data and the like read from a recording medium 605 to a receiving unit 602 through the transmission path 603, and outputs resulting sound and the like through an output unit 607). Here, “media data” is contents such as music data and video data. As shown in FIG. 1, the data transmitting apparatus 10 includes: a transmitting unit 601, a receiving unit 602, a transmission path 603, an input control unit 604, a recording medium 605 in which media data is stored, an output control unit 606, and an output unit 607.

In this embodiment, media data stored in the recording medium 605 is read by the input control unit 604, and the read media data is outputted to the transmitting unit 601. It is assumed here that media data is audio data. More specifically, it is assumed that the recording medium 605 is a disc medium such as a CD and the output unit 607 is a speaker.

The media data inputted to the transmitting unit 601 is processed (for example, encrypted and coded) in the transmitting unit 601, and transmitted to the transmission path 603.

The coded data transmitted to the transmission path 603 is received by the receiving unit 602, reconstructed to the original media data in the receiving unit 602, subjected to error detection, and outputted to the output control unit 606. The output control unit 606 receives an input of the media data outputted by the receiving unit 602, converts the media data to data which can be outputted by the output unit 607, and outputs the data. The output unit 607 reproduces audio based on the data outputted under control of the output control unit 606.

The transmitting unit 601 includes a check code inserting unit 610 and a coding unit 611.

The check code inserting unit 610 inserts error check codes into the media data inputted to the transmitting unit 601. Subsequently, the media data is coded in the coding unit 611 and transmitted to the transmission path 603.

The receiving unit 602 includes a decoding unit 620, a size storage unit 621, a check code detecting unit 622, and an error control unit 623.

The receiving unit 602 receives coded data from the transmission path 603. The coded data is decoded by the decoding unit 620. Subsequently, errors included in the decoded media data are detected by the check code detecting unit 622, and the result is passed to the error control unit 623. At this time, the check code detecting unit 622 performs error detection based on coding block size information stored in the size storage unit 621. Here, the coding block size information indicates the size of coding blocks to be coded. The error control unit 623 controls output of the media data to the output control unit 606 according to the result of error detection performed by the check code detecting unit 622 (for example, it performs a mute processing on the portions judged to be abnormal as having an error.) It is assumed here that a “coding block size” is the data size of each of the blocks coded by the coding unit 611, and that the same coding block size is determined by the system in advance for data to be coded by the coding unit 611 and for data to be stored in the size storage unit 621.

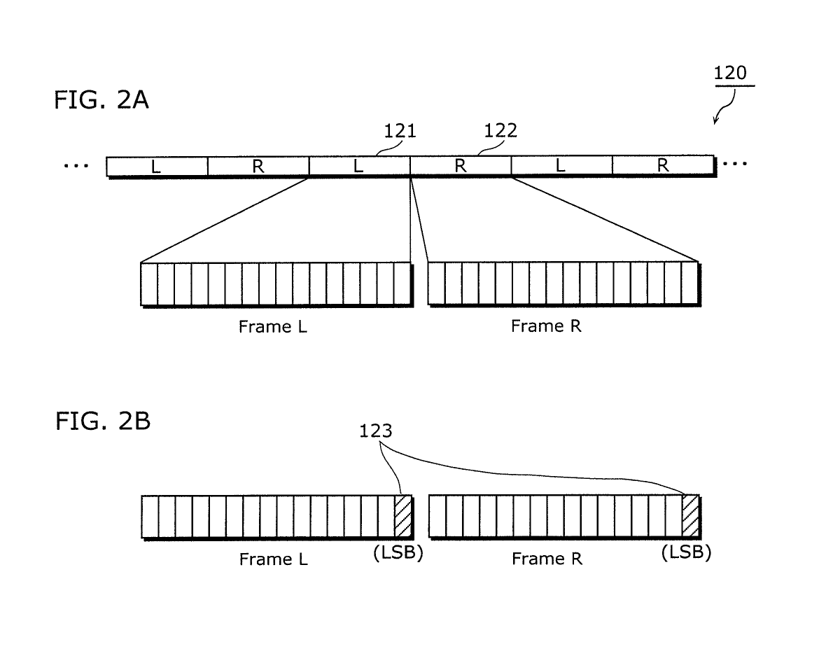

The media data inputted to the transmitting unit 601 in this embodiment has a frame data format as shown in FIG. 2A. Here, a “frame” means data obtained by separating, on a sampling cycle basis, media data corresponding to contents or processed media data including, for example, error check codes. More specifically, the media data in this embodiment is music data having a 2-channel PCM format in which left frames (Frames L) and right frames (Frames R) are arranged alternately. The bit length of each frame is 16 bits, and the least significant bit (LSB) of a frame and the most significant bit (MSB) of the next frame are consecutive.

The check code inserting unit 610 replaces even parity bits, which are assigned as error check codes to the media data, with the least significant bits (LSBs) 123 of the respective frames. The frames including the replaced bits are data having the same formats as those shown in FIG. 2B. Replacing the least significant bits 123 of the respective frames with error check codes makes it possible to perform error detection on music data without increasing the bandwidth necessary for the music data on the transmission path 603 while suppressing deterioration in sound quality.

The coding unit 611 performs data conversion such as encrypting and coding of data to be transmitted to the transmission path 603. Further, in the case where the size of the data inputted through the check code inserting unit 610 does not match the coding block size which is determined as the size of a unit to be coded, the coding unit 611 combines or separates the data in order to code the data on a coding block size basis.

In this embodiment, the coding unit 611 combines four frames (corresponding to 8 bytes) each of which has an error check code assigned by the check code inserting unit 610. This means that frames are combined to form a unit block having the coding block size which is coded in the next step.

In the next step, the combined frames are coded and outputted to the transmission path 603.

The coded data received by the receiving unit 602 through the transmission path 603 is inputted to the decoding unit 620 first.

The decoding unit 620 decodes the coded data inputted through the transmission path 603, and reconstructs it into frames assigned with error check codes. In other words, the decoding unit 620 performs decoding corresponding to the coding performed by the coding unit 611.

The size storage unit 621 is a recording medium such as an RAM in which coding block size information in this embodiment is stored.

The check code detecting unit 622 analyzes error check codes based on the frames assigned with error check codes outputted by the decoding unit 620 and the coding bock size information obtained from the size storage unit 621, and detects whether the decoded frames include any error or not.

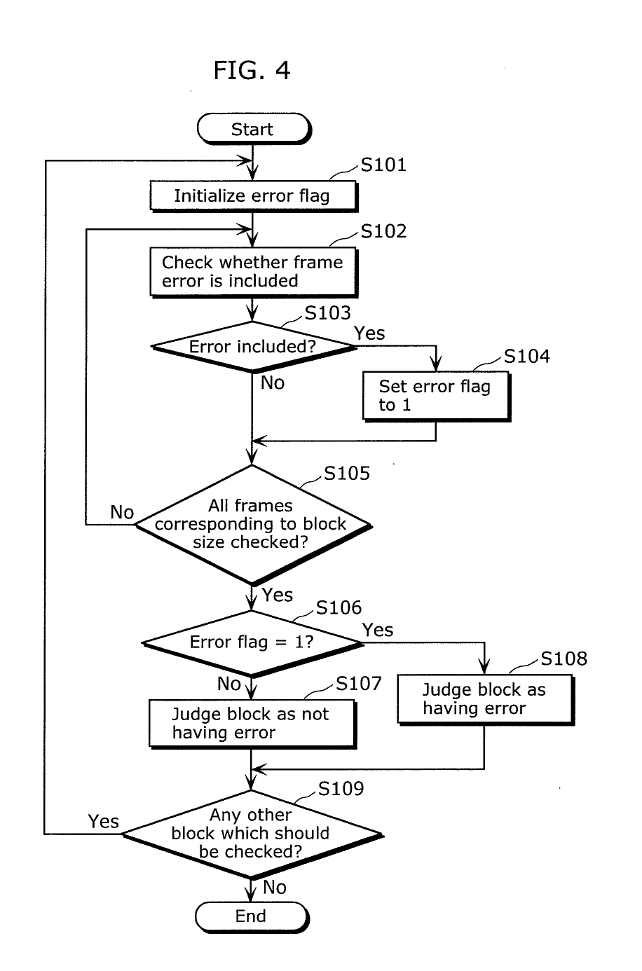

FIG. 4 is a flowchart of processes performed by the check code detecting unit 622 according to this embodiment.

The check code detecting unit 622 executes the following processes, on a coding block size basis, on the frames assigned with error check codes inputted through the decoding unit 620.

First, the check code detecting unit 622 initializes an error flag (Step S101), and checks whether or not each frame assigned with an error check code includes an error (Step S102). In this embodiment, since an error check code is an even parity, whether or not each inputted frame assigned with an error check code matches the even parity is checked here.

Next, in the case where the result of check performed in Step S102 shows that an inputted frame includes an error (Yes in Step S103), the check code detecting unit 622 sets the error flag to 1 (Step S104).

In the opposite case where the inputted frame does not include any error (No in Step S103), the check code detecting unit 622 checks whether or not error detection for all the frames corresponding to the coding block size has been completed (Step S105). In the case where such error detection has not been completed (No in Step S105), a transit to Step S102 is made to restart error detection for the remaining frames.

In the case where the error detection has been completed (Yes in Step S105), the check code detecting unit 622 checks whether or not the error flag of each of the frames is set to 1 (Step S106).

It is possible to judge whether or not an error has occurred at least once in a current unit block to be coded including frames by checking the error flag of the current unit block to be coded. In the case where the error flag of the current unit block to be coded shows 1 (Yes in Step S106), the frames included in the current unit block are judged as having an error (Step S108). In the opposite case where no error flag of the current block shows 1 (No in Step S106), the frames are judged as not having an error (Step S107). It should be noted that the check code detecting unit 622 repeats the processes (Step S101 to Step S108) as long as there remain blocks to be checked (Yes in Step S109).

The error control unit 623 performs an error processing (specifically, a mute processing) on all the frames included in the block judged as having an error based on the error detection information and frames outputted through the check code detecting unit 622 in order to prevent the media data from being outputted from the output control unit 606. As another error processing, it is possible to reduce noises by repeatedly outputting the normal frame which immediately precedes the frame judged as having the error instead of the abnormal frame.

The output control unit 606 performs digital-to-analog conversion, amplification and the like on the media data so that the succeeding output unit 607 reproduces sound resulting from the media data outputted through the error control unit 623.

The following describe operations performed in this embodiment in the case where no transmission error occurs on the transmission path 603.

The media data outputted through the input control unit 604 is inputted to the transmitting unit 601, is assigned with error check codes by the check code inserting unit 610, and is coded by the coding unit 611. Subsequently, the coded media data is transmitted to the receiving unit 602 through the transmission path 603, and is decoded and is subjected to error detection. Since no error has occurred on the transmission path 603, all the frames are judged to be normal in the checking of whether or not a current frame includes an error (Step S102) in the flowchart of FIG. 4. In this case, the media data outputted through the error control unit 623 is the same as the data outputted through the check code inserting unit 610. At this time, although the music data corresponding to 16 quantized bits to be reproduced through the output unit 607 is represented in 15 quantized bits, the output unit 607 can reproduce the music data having a sound quality slightly lower than that of the original music data.

The following describe operations performed in this embodiment in the case where a transmission error occurs on the transmission path 603.

The media data outputted through the input control unit 604 is inputted to the transmitting unit 601, is assigned with error check codes by the check code inserting unit 610, and is coded by the coding unit 611. Subsequently, the media data is inputted to the receiving unit 602 through the transmission path 603. It is assumed here that the media data is damaged due to noises coming from outside to the transmission path 603.

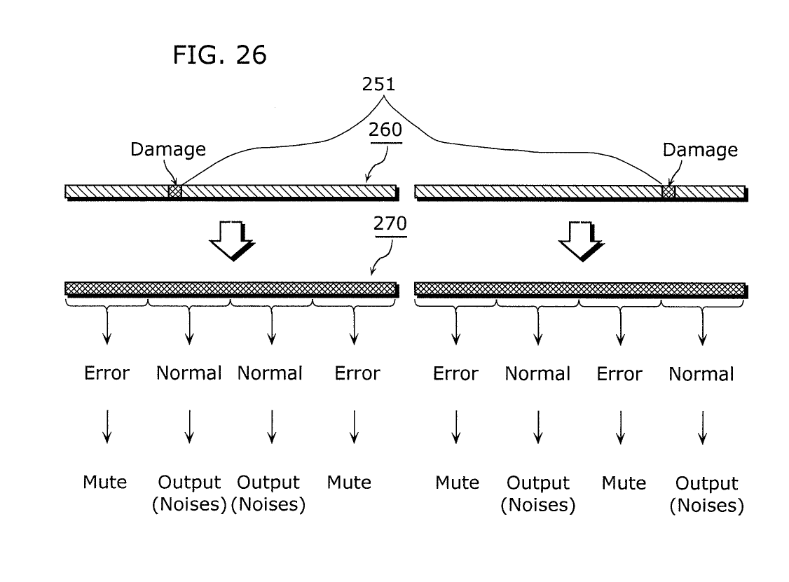

In this embodiment, it is assumed that coded data such as the coded block 260 in FIG. 26 is damaged due to an bit error. The damaged coded data is inputted to the receiving unit 602, and decoded by the decoding unit 620.

The respective decoded frames corresponding to the coding block size included in the damaged coded data have values different from those of the original data. In this case, since the error check code of each of the decoded frames is a parity bit, even frames including damaged data as shown in FIG. 26 are judged to be normal in some cases. If such abnormal frames are allowed to be reproduced, noises are generated.

The check code detecting unit 622 checks whether or not an error is included in each of the frames decoded by the decoding unit 620 according to the procedure shown in FIG. 4 (Step S102). In the case of a block 270 shown in FIG. 26, at least one error is detected in any of the frames corresponding to the coding block size. Thus, the error flag of the frames including errors is updated to 1 showing an error state (Step S104), and all the frames included in the coded block are judged as having an error (Step S108).

Since the frames have been judged as having the error by the check code detecting unit 622, the error control unit 623 performs an error processing such as a mute processing on all the frames corresponding to the coding block size.

Blocks including a frame judged as having an error are judged to be abnormal in this embodiment, but a sequence of blocks such as blocks adjacent to a block judged as having the error may be judged to be abnormal, and an error processing may be performed on the sequence of blocks.

As described above, this embodiment having a simple circuit for executing a simple error control procedure makes it possible to reduce noises while suppressing deterioration in sound quality caused by transmission errors generated on a transmission path without occupying an unnecessary transmission bandwidth.

### Second Embodiment

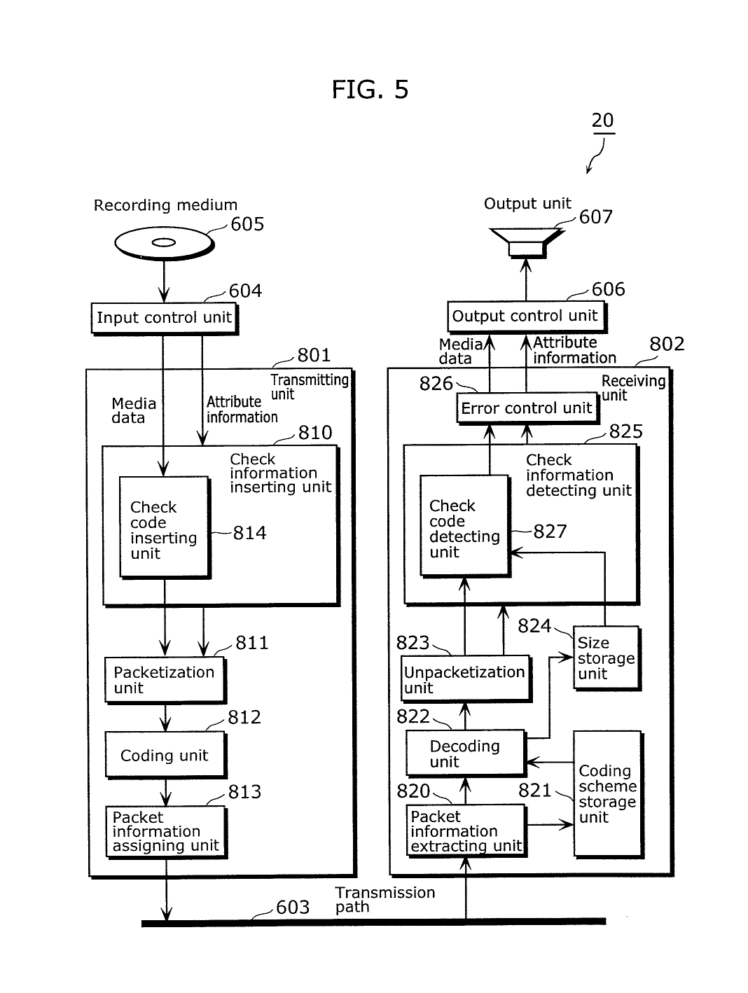

FIG. 5 is a block diagram of a functional structure of a data transmitting apparatus 20 in this embodiment.

The data transmitting apparatus 20 includes: a transmitting unit 801, a receiving unit 802, a transmission path 603, an input control unit 604, a recording medium 605, an output control unit 606, and an output unit 607. It should be noted that the same 15 structural units as those in the first embodiment are assigned with the same reference numerals, and the same descriptions are not repeated here.

The following embodiment describes an example where the media data stored in the recording medium 605 is read by the input control unit 604, and the read media data is transmitted to the receiving unit 802 through the transmitting unit 801 and the transmission path 603.

The media data outputted through the input control unit 604 is processed by the transmitting unit 801 and transmitted to the transmission path 603. The media data transmitted to the transmission path 603 is received by the receiving unit 802. The receiving unit 802 reconstructs the media data to the original media data, performs error detection on the reconstructed media data, and outputs it to the output control unit 606. The output control unit 606 receives an input of the media data outputted by the receiving unit 802, converts the media data to data which can be outputted by the output unit 607, and outputs the data.

The transmitting unit 801 includes: a check information inserting unit 810, a packetization unit 811, a coding unit 812, and a packet information assigning unit 813.

The check information inserting unit 810 inserts error check codes into media data inputted to the transmitting unit 801. Input control unit 604 inputs attribute information to the transmitting unit 801. Subsequently, the packetization unit 811 packetizes the respective data into packets. The coding unit 812 codes these packets.

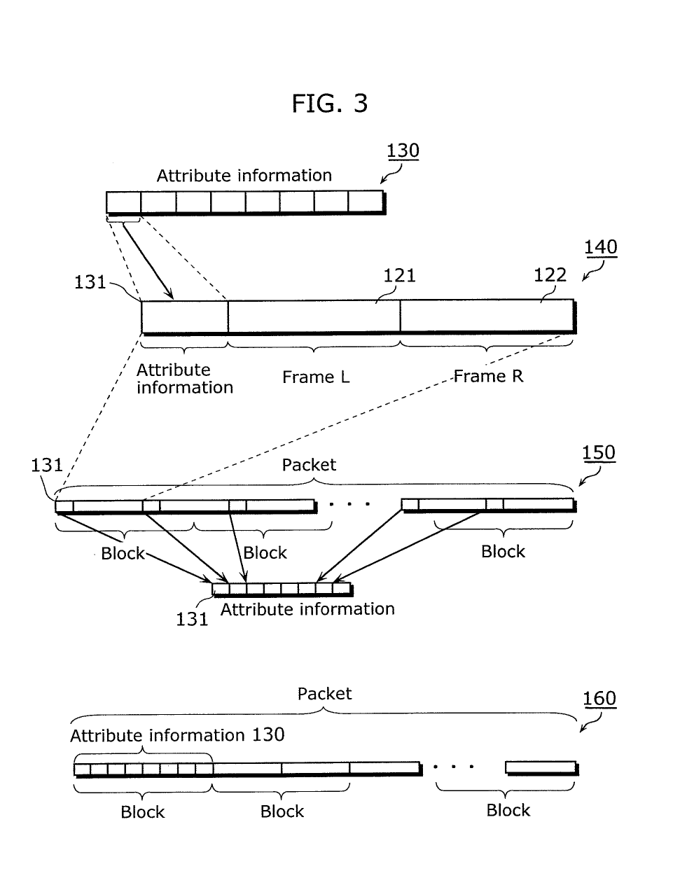

FIG. 3 is a diagram showing an example of a hierarchical structure of media data according to the present invention.

The attribute information 130 indicates the attributes of media data. Attribute information 130 includes: the name of a tune, the name of a music artist, the number of channels for the media data, the sampling frequency, the number of quantized bits, and copyright protection information. As known above, the attribute information 130 of a tune is basically constant. The attribute information 130 is represented in several bytes.

A frame 140 is obtained by segmenting the attribute information 130 into a predetermined unit of media data (for example, into a left-side Frame L 121 and a right-side Frame R 122).

The packet 150 is data obtained by combining several (for example, 8) frames 140. By grouping the attribute information included in a packet makes it possible to reconstruct the original attribute information 130.

Further, the packet 150 is structured with several coding unit blocks. A unit block is a minimum amount of data to be coded at a time (a coding unit block is also referred to simply as a “coding block” or “unit block”, and there are 5 coding blocks in FIG. 3).

A packet 160 has a format different from that of the packet 150. In the packet 160, attribute information 130 is arranged at the top, and media data is arranged next to the attribute information 130.

Transmission data which is classified into a data category and which is a minimum amount of data to be transmitted at a time is referred to as a unit of transmission data. More specifically, each of attribute information and frame data is a unit of transmission data.

Subsequently, the packet information assigning unit 813 assigns packet control information (packet information) for the coded packet, and transmits it to the transmission path 603.

The receiving unit 802 includes: a packet information extracting unit 820, a coding scheme storage unit 821, a decoding unit 822, an unpacketization unit 823, an unpacketization unit size storing unit 824, a check information detecting unit 825, and an error control unit 826.

The receiving unit 802 receives a packet through the transmission path 603, extracts the packet information from the received packet, and stores the packet information in the coding scheme storage unit 821.

The packet from which the packet information has been extracted is inputted to the decoding unit 822 and decoded. Subsequently, the unpacketization unit 823 separates the packet into frames and the attribute information. The data of these frames and the attribute information are inputted to the check information detecting unit 825. The check information detecting unit 825 performs error detection on the data, and outputs it to the error control unit 826. Packet size information indicating a target range on which error detection is performed is stored in the size storage unit 824. At this time, the check information detecting unit 825 performs error detection based on the packet size information.

The error control unit 826 controls output of media data using error detecting information detected by the check information detecting unit 825.

In this embodiment, the media data inputted to the transmitting unit 801 has the same format as that of the data 120 shown in FIG. 2A. Further, the media data is music data having a 2-channel PCM format. In the media data, a left-side frame (Frame L) 121 and a right-side frame (Frame R) 122 are arranged alternately. The bit length of each frame is 16 bits, and the least significant bit (LSB) of a frame and the most significant bit (MSB) of the next frame are consecutive.

The media data and attribute information is inputted to the check information inserting unit 810. Subsequently, the check information inserting unit 810 inserts error check codes into the inputted media data. More specifically, the check code inserting unit 814 inserts the error check codes to the media data.

In this embodiment, the check code inserting unit 814 replaces even parity bits, which are assigned to the media data as error check codes, with the least significant bits (LSBs) of the respective frames. The frames including the replaced bits are data having the same formats as those shown in FIG. 2B. Replacing the least significant bits of the respective frames with error check codes makes it possible to assign error check codes on music data without increasing the bandwidth necessary for the music data on the transmission path while suppressing deterioration in sound quality.

The packetization unit 811 receives inputs of frames assigned with attribute information and error check codes, and packetizes these frames into packets according to a predetermined rule. In this embodiment, the packetization unit 811 arranges pairs of the frames to which the check code inserting unit 814 has assigned error check codes and the attribute information, and packetizes these pairs into packets each of which includes several pairs.

The coding unit 812 performs data conversion such as encrypting and coding on data to be transmitted through the transmission path 603. In the case where the coding unit 812 codes inputted data whose size does not match the coding block size predetermined as the size of a unit to be coded, the coding unit 812 combines or separates the data in order to code the inputted data on a coding block size basis.

In this embodiment, packet data is segmented into coding blocks having the coding block size first. As the next step, the packet data is coded on a coding block size basis.

The packet information assigning unit 813 assigns packet information to the packets coded by the preceding coding unit 812. Here, “packet information” indicates the positions of the boundaries between packets and the coding schemes of the packets. The packet boundary positions are used for recognizing the portions corresponding to the packets in the data received by the receiving unit 802. The coding schemes are information for allowing a receiving-side apparatus to recognize the coding schemes of the packets. The receiving unit 802 can decode the packets properly by decoding them according to the specified formats. Packet information is used for preventing the data on the transmission path 603 from being intercepted. For example, the coding schemes of packets are changed according to time, and the encryption keys for packets are changed in the case where these packets are encrypted.

The packets assigned with packet information by the packet information assigning unit 813 are transmitted to the transmission path 603. The coded data transmitted through the transmission path 603 and received by the receiving unit 802 is inputted to the packet information extracting unit 820 first.

The packet information extracting unit 820 separates the packets by extracting the packet information from the received data, and stores the coding schemes extracted from the packet information into the coding scheme storage unit 821.

The coding scheme storage unit 821 is a recording medium such as an RAM in which the coding schemes extracted from the packet information extracted by the packet information extracting unit 820 are stored.

The decoding unit 822 decodes the data inputted through the packet information extracting unit 820, according to the coding schemes stored in the coding scheme storage unit 821. Since the coding schemes stored in the coding scheme storage unit 821 are determined on a packet-by-packet basis, the decoding unit 822 applies, in the decoding, the same coding scheme to the respective packets each of which includes several coding blocks.

The unpacketization unit 823 separates the frames and the attribute information respectively from the packets inputted through the decoding unit 822. The separated frames and attribute information are passed to the check information detecting unit 825.

The size storage unit 824 is a recording medium such as an RAM in which the packet size information and coding block size information processed in this system are stored. The packet sizes and coding block sizes shown in this information match those of the packets to be transmitted.

The check information detecting unit 825 detects whether or not any error has occurred in the transmission data, based on the frames and the attribute information inputted by the unpacketization unit 823 and the size information to be obtained from the size storage unit 824.

The check code detecting unit 827 detects whether or not any error has occurred in the frames by judging the error check codes of the frames to be inputted through the unpacketization unit 823, based on the frames with error check codes which are inputted through the unpacketization unit 823, and the coding block size information and the packet size information which are inputted through the size storage unit 824.

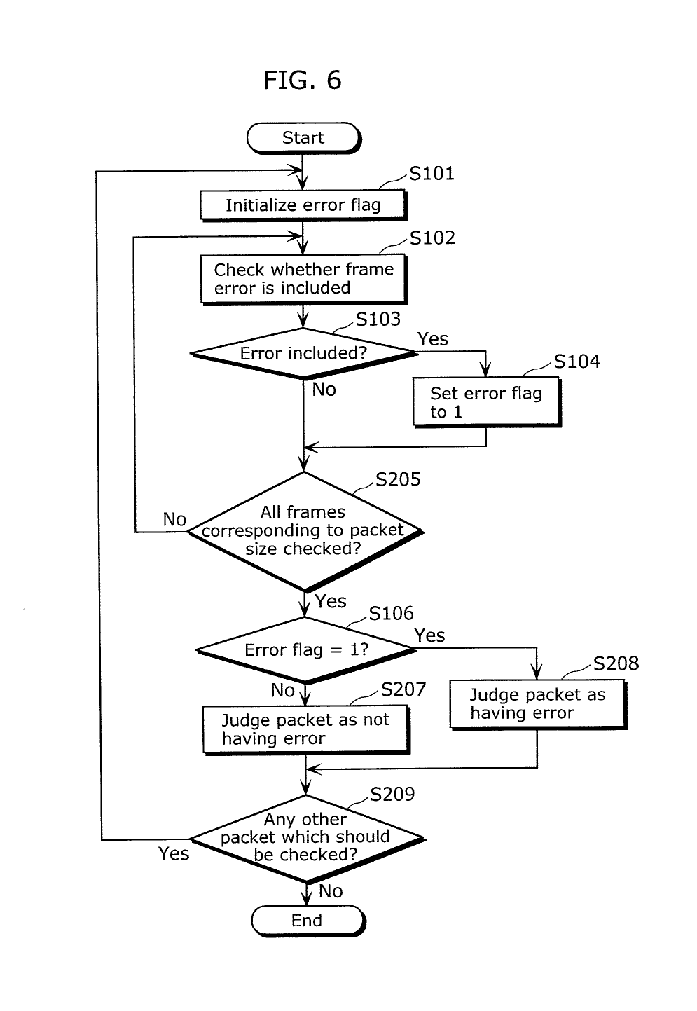

FIG. 6 is a flowchart of processes performed in the check code detecting unit 827. It should be noted that the same processes in FIG. 6 as those in FIG. 4 are assigned with the same reference numerals, and the same descriptions are not repeated here.

The check code detecting unit 827 stores the detected error states on a packet-by-packet basis (Step S104). In the case where there is an abnormal packet, the check code detecting unit 827 sets the error flag for the packet to 1.

Next, the check code detecting unit 827 checks whether or not error detection for all the frames corresponding to the packet size has been completed, based on the information stored in the size storage unit 824 (Step S205). In the case where such error detection for the frames corresponding to the packet size has not been completed (No in Step S205), a transit to Step S102 is made to restart error detection for the remaining frames. In the case where such error detection has been completed (Yes in Step S205), the check code detecting unit 827 checks whether or not an error is included on a packet-by-packet basis (Step S106).

It is possible to judge whether an error has occurred at least once in a current unit block to be coded including frames by checking the error flag of a current coded block to be processed. In the case where the error flag of a frame included in the current coded block to be processed is set to show an error state, the frames included in the current packet to be processed are judged as having an error (Step S208). In the case where no error flag shows an error state, the frames included in the current packet are judged as not having an error (Step S207). It should be noted that the check code detecting unit 827 repeats the processes (Steps S101 to S208) as long as there remain packets which should be checked (Yes in Step S209).

The error control unit 826 associates the frames and the error detection information outputted by the check information detecting unit 825, and performs an error processing on the frames judged as having the error in order to prevent the media data from being outputted through the output control unit 606. As another error processing, it is possible to reduce noises by repeatedly outputting the normal frame located immediately before the frame judged as having the error instead of the abnormal frame.

The attribute information outputted through the check information detecting unit 825 can also be associated with the error detection information. For example, in the case where an error has occurred in a frame included in a packet, it is possible to notify the system of an error by using the attribute information of the frame with the error in the packet or to prevent the current attribute information from being overwritten with the abnormal attribute information.

The following describe operations performed in this embodiment in the case where no transmission error occurs on the transmission path 603.

The media data and attribute information outputted through the input control unit 604 are inputted to the transmitting unit 801. The media data is assigned with error check codes. The respective media data and attribute information are packetized and coded. The packets are assigned with packet information. These packets are inputted to the receiving unit 802 through the transmission path 603. The packet information is extracted from the packets, and the respective media data and attribute information are decoded. The packets are unpacketized and subjected to error detection. Since no error has occurred on the transmission path 603, all the frames of a current packet to be processed are judged to be normal in Step S102 of FIG. 6. In this case, the media data and attribute information outputted through the check information detecting unit 825 are the same as the data outputted through the check information inserting unit 810.

At this time, although the music data corresponding to 16 quantized bits to be reproduced through the output unit 607 is represented in 15 quantized bits, the output unit 607 can reproduce the music data having a sound quality slightly lower than that of the original music data.

Next, the following describe operations performed in this embodiment in the case where a transmission error occurs on the transmission path 603.

The media data and attribute information outputted through the input control unit 604 are inputted to the transmitting unit 801. The media data is assigned with error check codes. The respective media data and attribute information are packetized and coded. The packets are assigned with packet information. Subsequently, the packets are inputted to the receiving unit 802 through the transmission path 603. It is assumed here that the data of the packets are damaged due to noises coming from outside to the transmission path 603, resulting in bit error in the packet information.

The damaged data is inputted to the receiving unit 802. The packet information extracting unit 820 extracts the packet information. As described above, the data to be processed by the packet information extracting unit 820 includes packet information damaged on the transmission path 603. Thus, it is impossible to detect the positions of the packets properly or to extract the coding scheme of the packets properly. Thus, the coded packets passed to the decoding unit 822 and the coding schemes to be stored in the coding scheme storage unit 821 are different from the original coding packets and coding scheme.

The decoding unit 822 decodes the coded packets based on the packet information obtained from the packet information extracting unit 820 and the coding scheme information obtained from the coding scheme storage unit 821. Thus, in the case where one of the information is abnormal, the packet data obtainable through the decoding is different from the original data because the decoding unit 822 decodes the coded packets based on the abnormal information.

It is assumed here that all the frames and attribute information included in the decoded packets have values different from those of the original data. In the case of the same decoded blocks as the block 270 in FIG. 26, each of the decoded frames has a parity bit as the error check code. Thus, there may be cases where even abnormal frames are judged to be normal in the error detection performed on a frame-by-frame basis although these frames have damaged data. If these abnormal frames are judged to be normal and reproduced according to a conventional technique, noises are generated. Since attribute information is not assigned with an error check code, it is impossible to detect damaged attribute information.

Next, the unpacketization unit 823 separates the frames and the attribute information. The check code detecting unit 827 performs error detection on the frames according to the procedure shown in FIG. 6. In this case, at least one error is detected in the frames corresponding to the packet size. Thus, the error flag of the frame including the error is set to 1 showing an error state in Step S104, and all the frames and attribute information included in the packet including the error frame are judged as having an error in Step S106. Subsequently, the error control unit 826 performs a mute processing on the frames corresponding to the packet size judged as having the error by the check code detecting unit 827. In addition, the attribute information of the packets including the abnormal frame is also recognized as abnormal.

As described above, the data transmitting apparatus according to this embodiment with a simple circuit for executing a simple error control procedure makes it possible to reduce noises by suppressing deterioration in sound quality caused by transmission errors generated on a transmission path without occupying an unnecessary transmission bandwidth. The data transmitting apparatus detects whether or not packet information is damaged without assigning error check codes to data, such as packet information, important in the data transmission. This makes it possible to perform noise reduction control and detection of damage in attribute information.

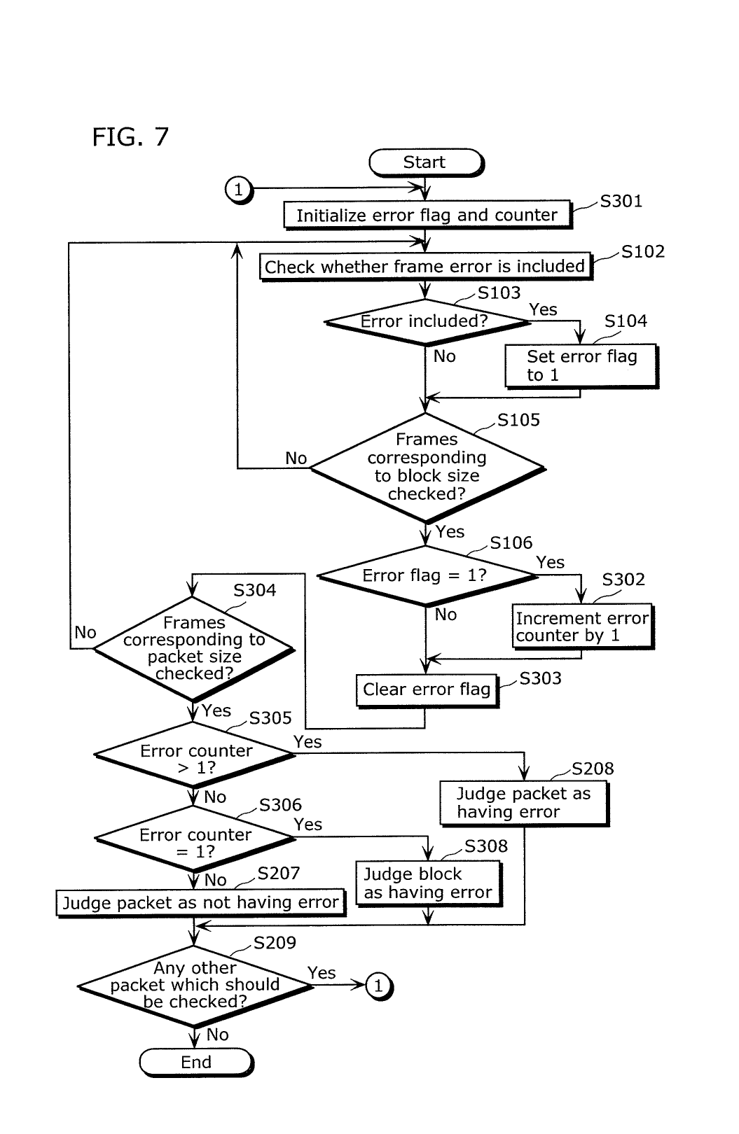

Next, a variation of this embodiment is described. FIG. 7 is a flowchart of processes performed by a variation of the check code detecting unit 827 in FIG. 5. It should be noted that the same processes in FIG. 7 as those in FIGS. 4 and 6 are assigned with the lo same reference numerals, and the same descriptions are not repeated here.

The check code detecting unit 827 executes the following processes on the packets to be inputted through the unpacketization unit 823 on a packet-by-packet basis.

First, the check code detecting unit 827 initializes an error flag and an error counter (Step S310), and checks whether or not an error is included in each coded block, based on an error check code assigned to each frame (Steps S102 to S105).

Further, the check code detecting unit 827 counts, for each packet, the number of abnormal coded blocks included in the packet (Step S302).

Next, the check code detecting unit 827 clears the error flag (Step S303) in order to end the processing for a coded block and become ready for error detection on the next coded block.

Further, the check code detecting unit 827 checks whether or not error detection for all the frames corresponding to the packet size has been completed, based on the size information stored in the size storage unit 824 (Step S304).In the case where such error detection for the frames corresponding to the packet size has not been completed (No in Step S304), a transit to Step S102 is made to restart error detection for the remaining frames.

In the opposite case where such error detection has been completed (Yes in Step S304), the check code detecting unit 827 checks whether or not the error counter is greater than 1 (Step S305). This makes it possible to judge whether two or more errors have occurred in the coded blocks in a current packet to be processed. In the case where two or more abnormal coded blocks are included in the current packet (Yes in Step S305), all the frames included in the current packet are judged as having an error (Step S208). In addition, in the case where an error has occurred in a coded block in a current packet to be processed (Yes in Step S306), it is judged that an abnormal coding block is included (Step S308).

It should be noted that the data transmitting apparatus 20 according to this embodiment stores, in the size storage unit 824, at least one piece of information for identifying the block judged as having the error in Step S308.

This makes it possible to judge the number of errors in the coded blocks in a current packet to be processed. In the case where only one error has occurred in a coded block in a current packet to be processed, the check code detecting unit 827 judges that all the frames in the coded block to be processed and the attribute information of the coded block are abnormal, and judges that the data of the other coded blocks in the current packet are normal.

In the opposite case where no error has occurred in the coding blocks in a current packet to be processed (No in Step S306), the check code detecting unit 827 judges that all the frames and attribute information included in the current packet are normal (Step S207).

The following describe operations performed by this variation in the case where an error occurs on the transmission path 603, resulting in damage to packet information.

The media data and attribute information outputted through the input control unit 604 are inputted to the transmitting unit 801. The media data is assigned with error check codes. The respective media data and attribute information are packetized and coded. The packets are assigned with packet information. Subsequently, the packet is inputted to the receiving unit 802 through the transmission path 603. It is assumed here that the data of the packet is damaged due to noises coming from outside to the transmission path 603, resulting in a bit error in the packet information.

The damaged data is inputted to the receiving unit 802. The packet information extracting unit 820 extracts the packet information. As described above, the data to be processed by the packet information extracting unit 820 includes packet information damaged on the transmission path 603. Thus, it is impossible to detect the positions of the packets properly or to extract the coding scheme of the packets properly. Thus, the coded packets passed to the decoding unit 822 and the coding scheme to be stored in the coding scheme storage unit 821 are different from the original coding packets and coding schemes.

The decoding unit 822 decodes the coded packets based on the packet information obtained from the packet information extracting unit 820 and the coding scheme information obtained from the coding scheme storage unit 821. Thus, in the case where one of the information is abnormal, the packet data obtainable through the decoding is different from the original data because the decoding unit 822 decodes the coded packets based on the abnormal information.

It is assumed here that all the frames and attribute information included in the decoded packets have values different from those of the original data. In the case of the same decoded blocks as the block 270 in FIG. 26, each of the decoded frames has a parity bit as the error check code. Thus, there may be cases where even abnormal frames are judged to be normal in the error detection performed on a frame-by-frame basis although these frames have damaged data. If these abnormal frames are judged to be normal and reproduced according to a conventional technique, noises are generated. Since attribute information is not assigned with an error check code, it is impossible to detect damaged attribute information.

Next, the unpacketization unit 823 separates the frames and the attribute information. The check code detecting unit 827 performs error detection on the frames according to the procedure shown in FIG. 7. In the case where error detection is performed on the frames corresponding to a packet size and three coded blocks are judged as having an error (in other words, the error counter of the packet shows 3 in Step S302), the check code detecting unit 827 judges that all the frames and attribute information included in the packet are abnormal.

Since all the frames in the packet are judged as having the error by the check code detecting unit 827, the error control unit 826 performs a mute processing on the frames. In addition, the attribute information of the packet including the abnormal frame is also recognized as abnormal.

The following describe operations performed by this variation in the case where an error has occurred on the transmission path 603, resulting in damage to 1-bit data other than packet information.

The media data and attribute information outputted through the input control unit 604 are inputted to the transmitting unit 801. The media data is assigned with error check codes. The respective media data and attribute information are packetized and coded. The packets are assigned with packet information. Subsequently, the media data is inputted to the receiving unit 802 through the transmission path 603. It is assumed here that the media data is damaged due to noises coming from outside to the transmission path 603, which causes a bit error resulting in damage to coded data other than the packet information.

The damaged data is inputted to the receiving unit 802. The packet information extracting unit 820 extracts the packet information. The packet information is stored in the coding scheme storage unit 821.

The decoding unit 822 decodes the coded packets based on the packet information obtained from the packet information extracting unit 820 and the coding scheme information obtained from the coding scheme storage unit 821. Thus, in the case where the information from the packet information extracting unit 820 is abnormal, the packet data obtainable through the decoding is different from the original data because the decoding unit 822 decodes the coded packets based on the abnormal information.

It is assumed here that all the frames and attribute information included in the decoded blocks have values different from those of the original data. In the case of the same decoded blocks as the block 270 in FIG. 26, each of the decoded frames has a parity bit as the error check code. Thus, even abnormal frames are judged to be normal in the error detection although these frames have damaged data. If these abnormal frames are judged to be normal and reproduced according to a conventional technique, noises are generated. Since attribute information is not assigned with an error check code, it is impossible to detect damaged attribute information.

Next, the unpacketization unit 823 separates the frames and the attribute information. The check code detecting unit 827 performs error detection on the frames according to the procedure shown in FIG. 7. In the case where a coded block is judged as having an error when error detection is performed on the frames corresponding to a packet size, the error counter for the packet shows 1. At this time, all the frames and attribute information of the coded block including the abnormal frame are judged as having the error. The error control unit 826 performs a mute processing on the frames corresponding to the coded block judged as having the error by the check code detecting unit 827. In addition, the attribute information included in the current coded block is also recognized as abnormal. There may be cases where attribute information indicating a single meaning is separately arranged into several coded blocks. In this case, only the attribute information included in the coded block judged as having the error may be regarded as abnormal, and other attribute information included in a coded block which is actually normal may be regarded as abnormal.

Conceivable errors which occur on the transmission path 603 include: 1-bit data error which occurs accidentally; and burst errors such as data errors which occur in plural bits. In the case where burst errors have occurred, it is expected that several coded blocks are judged as having an error. In this case, the packets included in the coded blocks are judged as having an error, which makes it possible to reduce the risk of occurrence of noises. In the case where 1-bit data error has occurred in important information such as packet information, it is expected that several coded blocks are judged as having an error. In this case, it is possible to reduce the risks of occurrence of noises due to damage in the whole packet. In the case where 1-bit data error has occurred in data other than packet information, it is possible to minimize the range during which sound output is stopped by minimizing the number of frames judged as having an error. This is because it is very unlikely that two or more accidental errors occur in a single packet on a sufficiently reliable transmission path. Such being the case, it becomes possible to reduce noises efficiently by changing the target range for error detection using an error counter.

As described above, the data transmitting apparatus according to this variation with a simple circuit for executing a simple error control procedure makes it possible to reduce noises by suppressing deterioration in sound quality caused by transmission errors generated on a transmission path without occupying an unnecessary transmission bandwidth. The data transmitting apparatus can detect damage in packet information without assigning error check codes to data, such as packet information, important in the data transmission, perform noise reduction control, and detect damage in attribute information. In addition to this, the data transmitting apparatus in this variation is capable of preventing normal data from being a target to be judged as having an error by changing, based on the number of errors in a packet, the frames and attribute information which is a target to be judged as having an error, minimizing the targets on which a mute processing is performed.

### Third Embodiment

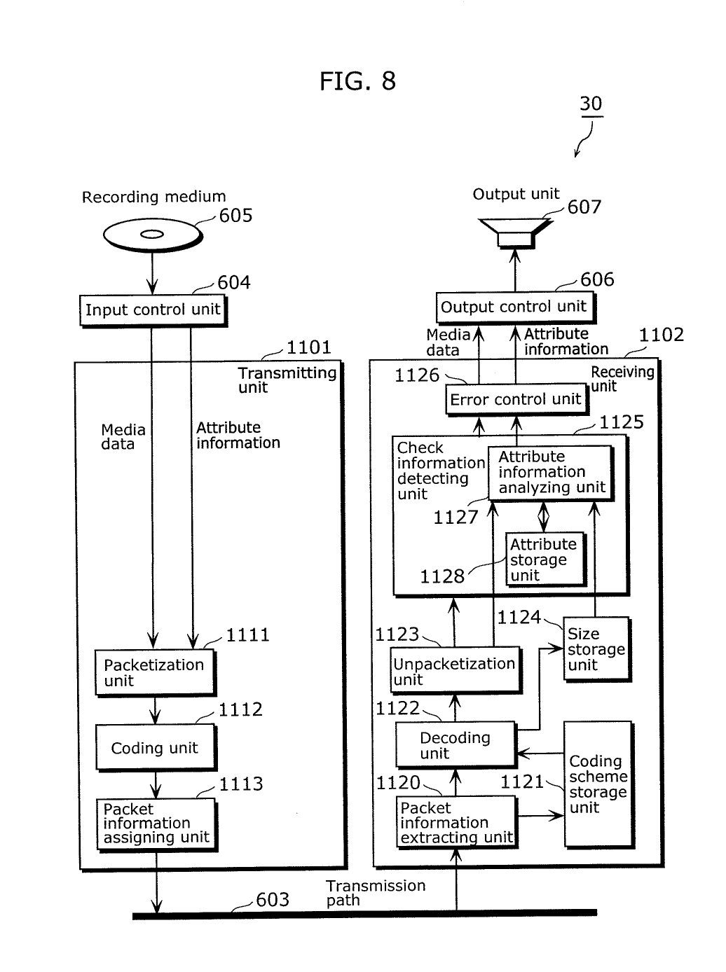

FIG. 8 is a block diagram of a functional structure of a data transmitting apparatus 30 in this embodiment.

The data transmitting apparatus 30 includes: a transmitting unit 1101, a receiving unit 1102, a transmission path 603, an input control unit 604, a recording medium 605, an output control unit 606, and an output unit 607. It should be noted that the same constituent units as those in the first embodiment and the second embodiment are assigned with the same reference numerals, and the same descriptions are not repeated here.

The following embodiment describes an example where the media data stored in the recording medium 605 is read by the input control unit 604, and the read media data is inputted in the transmitting unit 110.

The media data and attribute information are inputted to the transmitting unit 1101. The transmitting unit 1101 processes and transmits the media data to the transmission path 603. The receiving unit 1102 receives the data transmitted through the transmission path 603, reconstructs the data into media data and attribute information, performs error detection on the data and information and output them to the output control unit 606. The output control unit 606 outputs a signal to the output unit 607, and the output unit 607 reproduces sound from the signal.

This embodiment utilizes the attribute information inputted to the transmitting unit 1101 as error check information.

The transmitting unit 1101 includes: a packetization unit 1111, a coding unit 1112 and a packet information assigning unit 1113.

The packetization unit 1111 packetizes the respective media data and attribute information inputted to the transmitting unit 1101 into packets. The coding unit 1112 codes these packets. Subsequently, the packetization information assigning unit 1113 assigns the packets control information of the packets, and outputs the packets to the transmission path 603.

The receiving unit 1102 includes: a packet information extracting unit 1120, a coding scheme storage unit 1121, a decoding unit 1122, an unpacketization unit 1123, a size storage unit 1124, a check information detecting unit 1125, an error control unit 1126.

The receiving unit 1102 receives data from the transmission path 603. The packet information extracting unit 1120 extracts the packet information from the packets. The packet information is stored in the coding scheme storage unit 1121.

The packets from which the packet information has been extracted are inputted to the decoding unit 1122 and decoded. Subsequently, the unpacketization unit 1123 separates each of the packets into frames and the attribute information. Subsequently, the check information detecting unit 1125 receives inputs of the frames and attribute information, performs error detection on the data, and passes the result to the error control unit 1126. At this time, the check information detecting unit 1125 performs error detection based on packet size information indicating the target range for the error detection stored in the size storage unit 1124.

The error control unit 1126 controls output of the media data according to error detection information obtained through the check information detecting unit 1125.

In this embodiment, the media data which is inputted to the transmitting unit 1101 has the same format as that of the data 120 in FIGS. 2A and 2B. Further, the media data is music data having a 2-channel PCM format in which a left frame (Frame L) and a right frame (Frame R) are arranged alternately. The bit length of each frame is 16 bits, and the least significant bit (LSB) of a frame and the most significant bit (MSB) of the next frame are consecutive.

The packetization unit 1111 receives inputs of the frames and the attribute information, and packetizes these frames into packets according to a predetermined rule.

In this embodiment, the packetization unit 1111 arranges pairs of frames and attribute information in the same manner as the pairs of frames in the packet 140 in FIG. 3 so as to form a packet 150.

The coding unit 1112 performs data conversion such as encrypting on data to be transmitted through the transmission path 603. In the case where the coding unit 1112 codes inputted data whose size does not match the coding block size predetermined as the size of a unit to be coded, the coding unit 1112 combines or separates the data in order to code the inputted data on a coding block size basis.

In this embodiment, first, packet data is segmented into coding blocks having the same predetermined coding block size as that of the packet 150 in FIG. 3. As the next step, the packet data is coded on a coding block size basis.

The packet information assigning unit 1113 assigns packet information to the packets coded by the preceding coding unit 1112. Here, “packet information” indicates the positions of the boundaries between packets and the coding schemes of the packets. The packet boundary positions are used for recognizing the portions corresponding to the packets in the data received by the receiving unit 1102. The coding schemes are information for allowing the receiving-side unit 1102 to recognize the coding schemes of the packets. The receiving unit 1102 can decode the packets properly by decoding them according to the specified formats. Packet information is used for making it difficult to intercept the data on the transmission path 603. For example, the coding schemes of packets are changed according to time, and the encryption keys for packets are changed in the case where these packets are encrypted.

The packets assigned with packet information by the packet information assigning unit 1113 are transmitted to the transmission path 603. The coded data transmitted through the transmission path 603 and received by the receiving unit 1102 is inputted to the packet information extracting unit 1120 first.

The packet information extracting unit 1120 separates the packets by extracting the packet information from the received data, and stores the coding schemes extracted from the packet information into the coding scheme storage unit 1121.

The coding schemes extracted from the packet information extracted by the packet information extracting unit 1120 are stored in the coding scheme storage unit 1121.

The decoding unit 1122 decodes the data inputted through the packet information extracting unit 1120, according to the coding schemes stored in the coding scheme storage unit 1121. Since the coding schemes stored in the coding scheme storage unit 1121 are determined on a packet-by-packet basis, the decoding unit 1122 applies, in the decoding, the same coding schemes to the respective packets each of which includes several coding blocks.

The unpacketization unit 1123 separates the frames and the attribute information respectively from the packets inputted through the decoding unit 1122. The separated frames and attribute information are passed to the check information detecting unit 1125.

The size storage unit 1124 is a unit for recording the packet size information and coding block size information processed in this system. The packet sizes and coding block sizes shown in this information match those of the packets to be transmitted.

The check information detecting unit 1125 detects whether or not any error has occurred in the transmission data, based on the frames and attribute information inputted by the unpacketization unit 1123 and the size information to be obtained from the size storage unit 1124.

The attribute information analyzing unit 1127 analyzes whether or not the received sequence of attribute information is valid using the attribute information inputted through the unpacketization unit 1123 and the packet size information obtained from the size storage unit 1124. The attribute information analyzing unit 1127 judges the validity of the sequence of attribute information of each packet by comparing the attribute information of the current packet and the attribute information of the immediately-preceding packet.

The check information detecting unit 1125 includes: an attribute information analyzing unit 1127 and an attribute storage unit 1128.

The attribute storage information 1128 is used for holding the attribute information of the immediately-preceding packet so that the attribute information analyzing unit 1127 can check the validity of the sequence of attribute information of the current packet.

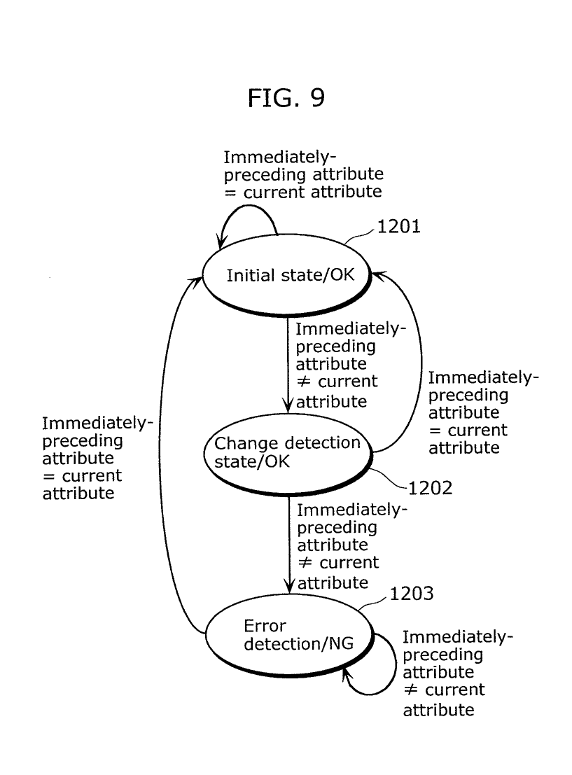

FIG. 9 is a diagram showing the transitions of states at the time of error detection performed in the attribute information analyzing unit 1127 in this embodiment. In FIG. 9, ellipses show states between which transitions are made according to conditions at the times when these transitions between the states are triggered. Here, the reception of the attribute information corresponding to a packet triggers the comparison between the attribute information of the current packet and the attribute information of the immediately-preceding packet, and the state transition according to the result of the comparison is made. A judgment of “OK” or“No” in FIG. 9 shows the error state of the packet immediately preceding a current packet. A judgment of “OK” shows that the immediately-preceding packet is not abnormal, and a judgment of “NG” shows that the immediately-preceding packet is abnormal.

A state 1201 shows the initial state. This state shows that the attribute information is constant, and that no error has been detected in the immediately-preceding packet. A return to the state 1201 is made in the case where a packet is received and the attribute information of the current packet matches the attribute information of the immediately-preceding packet, and a judgment that the immediately-preceding packet is normal is made at this time. In the case where the attribute information of the current packet does not match the attribute information of the immediately-preceding packet, a transition to a state 1202 is made. In the case where both the packets before and after the current packet have constant attribute information, the packet before the current packet is judged to be normal.

A state 1202 shows a change detection state. This change detection state shows that current attribute information has been changed from the immediately-preceding attribute information although the previous comparison showed that the attribute information was constant. In the case where a packet is received and the attribute information of the current packet matches the attribute information of the immediately-preceding packet in this state, the sequence of attribute information can be judged to be valid, and a transition to the state 1201 is made. At this time, the immediately-preceding packet can be judged to be normal. In the case where the attribute information of the current packet does not match the attribute information of the immediately-preceding packet, a judgment that an error has occurred in the attribute information is made because the attribute information of these packets in the attribute information sequence is not identical to each other, and a transition to the state 1203 is made. At this time, the immediately-preceding packet is judged as having an error.

A state 1203 shows an error detection state. In the case where a packet is received and the attribute information of the current packet matches the attribute information of the immediately-preceding packet in this state, it is judged that the packet is normal, that is, a valid attribute information sequence has been observed again, and a transition to the state 1201 is made. At this time, the immediately-preceding packet can be judged to be normal. In the case where the attribute information of the current packet does not match the attribute information of the immediately-preceding packet, a judgment that an error has occurred in the attribute information is made because the attribute information of these packets in the attribute information sequence is still not identical to each other, and a transition to the state 1203 is made. At this time, the immediately-preceding packet is judged as having an error.

Performing error detection according to the state transitions in FIG. 9 makes it possible to: stop outputting sound by canceling the noises when errors have been detected; and judge a normal transmission state has returned when the attribute information is constant for a predetermined time, and restart outputting the sound.

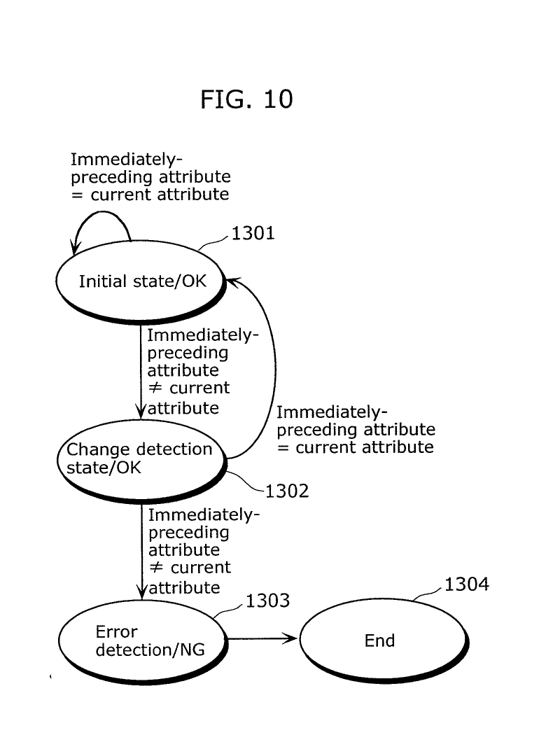

FIG. 10 is a diagram showing the transitions of states analyzed in the attribute information analyzing unit 1127 in this embodiment.

Here, the reception of the attribute information corresponding to a packet triggers the comparison between the attribute information of the current packet and the attribute information of the immediately-preceding packet, and the state transition according to the result of the comparison is made. A judgment of “OK” or “NO” shows the error state of the immediately-preceding packet.

A state 1301 shows the initial state. This state shows that the attribute information is constant, and that no error has been detected in the immediately-preceding packet. A return to the state 1301 is made in the case where a packet is received and the attribute information of the current packet matches the attribute information of the immediately-preceding packet, and a judgment that the immediately-preceding packet is normal is made at this time. In the case where the attribute information of the current packet does not match the attribute information of the immediately-preceding packet, a transition to a state 1302 is made. In the case where both the packets before and after the current packet have constant attribute information, the packet before the current packet is judged to be normal.

A state 1302 shows a change detection state. This state shows that current attribute information has been changed from the immediately-preceding attribute information although the immediately-preceding comparison showed that the attribute information was constant. In the case where a packet is received and the attribute information of the current packet matches the attribute information of the immediately-preceding packet in this state, the sequence of attribute information can be judged to be valid, and a transition to the state 1301 is made. At this time, the immediately-preceding packet can be judged to be normal. In the case where the attribute information of the current packet does not match the attribute information of the immediately-preceding packet, a judgment that an error has occurred in the attribute information is made because of a violation related to the attribute information sequence of these packets, and a transition to the state 1303 is made. At this time, the immediately-preceding packet is judged as having an error.

A state 1303 shows an error detection state. The state 1303 transits to the state 1304, and never transits to any other states. In this case, it is necessary to solve the cause of the transmission error, explicitly clear the state to initialize the state to the state 1301, and restart the transmission.

Performing error detection according to the state transitions in FIG. 10 makes it possible to prevent noises from being outputted even when an error state has been judged to be normal in a serious trouble including continuous errors, by explicitly returning the state to the initial state after the occurrence of the trouble.

The error control unit 1126 associates the frames and the error detection information outputted through the check information detecting unit 1125, and performs mute control in order to prevent the sound corresponding to the abnormal frames from being outputted through the output control unit 606. For example, it is possible to reduce noises by repeatedly outputting the normal frame located immediately before the abnormal frame instead of the abnormal frame.

The attribute information outputted through the check information detecting unit 1125 can also be associated with the error detection information. For example, in the case where an error has occurred in a frame included in a packet, it is possible to notify the system of an error by using the attribute information of the frame having the error in the packet or to prevent the current attribute information from being overwritten with the abnormal attribute information. The error detection information notified by the check information detecting unit 1125 shows the error state of the immediately-preceding packet. Thus, a mounted buffer has a capacity large enough to hold output data necessary for performing error control on the data judged as having the error by the error control unit 1126.

The output control unit 606 performs digital-to-analog conversion, amplification and the like on the media data outputted through the error control unit 1126 and stores the attribute information, so that the succeeding output unit 607 can refer to the 10 attribute information as necessary and reproduce the media data outputted through the error control unit 1126.

The following describe operations performed in this embodiment in the case where an attribute information sequence is normal.

First, the media data and the attribute information outputted through the input control unit 604 are inputted to the transmitting unit 1101. In the case where the media data is music data, since the attribute information shows the attributes of the music data, the attribute information of a tune is basically constant. Here, it is assumed that the attribute information inputted to the transmitting unit 1101 is “A” at first, and the attribute information changes to “B” when the next tune starts.

The frames and the attribute information are packetized by the packetization unit 1111, and coded by the coding unit 1112. The packet information assigning unit 1113 assigns packet information to the coded data, and outputs the coded data with packet information to the transmission path 603.

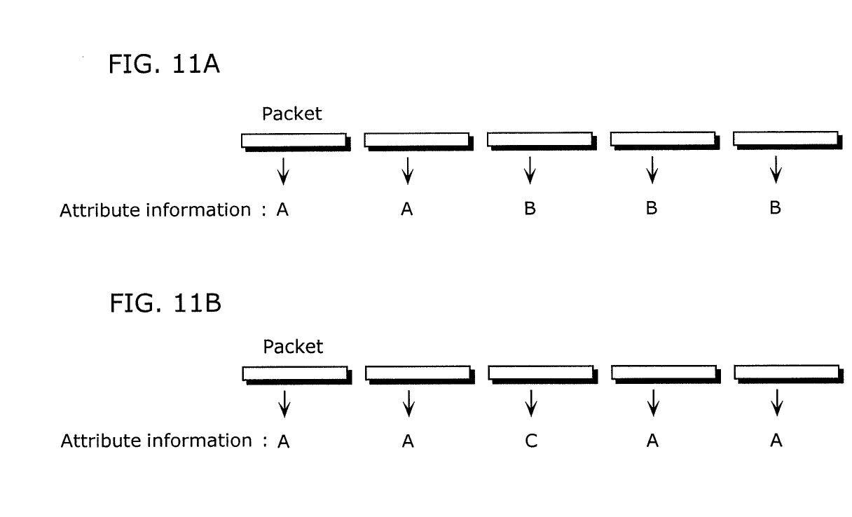

FIGS. 11A and 11B are diagrams showing examples of attribute information corresponding to several packets. Each of FIGS. 11A and 11B shows some of packets in a packet sequence which are being transmitted. FIG. 11A shows data outputted to the transmission path 603. FIG. 11A shows five packets and also shows that the attribute information changes from “A” to “B” when a tune changes to another tune at the third packet.

The packet information extracting unit 1120 extracts the packet information from the packets inputted to the receiving unit 1102 through the transmission path 603. The coding schemes of the packets are stored in the coding scheme storage unit 1121.

The decoding unit 1122 decodes the packets coded based on the information obtained through the packet information extracting unit 1120 and the coding scheme storage unit 1121. The unpacketization unit 1123 separates the attribute information and the frames. The attribute information analyzing unit 1127 performs error detection on each attribute information in the attribute information sequence by analyzing the attribute information sequence.

In the case where the attribute information analyzing unit 1127 performs error detection on the data in FIG. 11A, the state 1301 in FIG. 10 is observed at the time when the first and second packets are received, a transition to the state 1302 is made at the third packet, a return to the state 1301 is made at the fourth and fifth packets, and the packet sequence is judged to be normal.

The following describe operations performed at the time when an attribute information sequence is abnormal.

First, the media data and the attribute information outputted through the input control unit 604 are inputted to the transmitting unit 1101. Here, it is assumed that the attribute information inputted to the transmitting unit 1101 does not change, and that the attribute information outputted from the input control unit 604 is always constant within the range described below.

The frames and the attribute information are packetized by the packetization unit 1111, and coded by the coding unit 1112. The packet information assigning unit 1113 assigns packet information to the coded data, and outputs the coded data with packet information to the transmission path 603.

Here, it is assumed that a portion of a packet is deformed due to a transmission error on the transmission path 603. The data is inputted to the receiving unit 1102 through the transmission path 603. The packet information extracting unit 1120 extracts packet information from the data. The coding scheme of the data is stored in the coding scheme storage unit 1121.

The decoding unit 1122 decodes coded packets based on the information obtained from the packet information extracting unit 1120 and the coding scheme storage unit 1121 although the decoded data is different from the original data because of data damage caused on the transmission path 603.

FIG. 11B is a diagram showing an example of decoded packets and attribute information. The attribute information of each of the original packets of the transmitted data is “A”, and thus the attribute information of each of the decoded packets should be “A”. However, the attribute data of the third packet is deformed to “C”.

It is assumed that the data of the frames and the attribute information of the damaged decoded packets have values different from those of the original data.

The unpacketization unit 1123 separates the data into attribute information and frames. The attribute information analyzing unit 1127 performs error detection on each attribute information in the attribute information sequence by analyzing it.

In the case where the attribute information analyzing unit 1127 performs error detection on the data in FIG. 11B, the state 1301 is observed at the time when the first and second packets are received, and a transition to the state 1302 is made at the third packet. The attribute information of the current fourth packet does not match the attribute information of the third packet. Thus, a transition to the state 1303 is made and the third packet is judged as having an error.

Since the packet has been judged as having the error by the attribute information analyzing unit 1127 as described above, the error control unit 1126 performs a mute processing on the frames included in the current packet. In addition, the attribute information of the current packet is judged as having an error.

As described above, the data transmitting apparatus 30 of this embodiment has a simple circuit for executing a simple error control procedure in the receiving unit 1102, and thus is capable of reducing noises by suppressing deterioration in sound quality caused by transmission errors generated on the transmission path 603 without occupying an unnecessary transmission bandwidth. This eliminates the requirement that the transmitting unit 1101 has a special circuit for inserting error check information to data such as packet information and performs noise reduction control. The data transmitting apparatus can detect damage in packet information without assigning error check codes to data, such as packet information, important in the data transmission, perform noise reduction control, and detect damage in attribute information.

### Fourth Embodiment

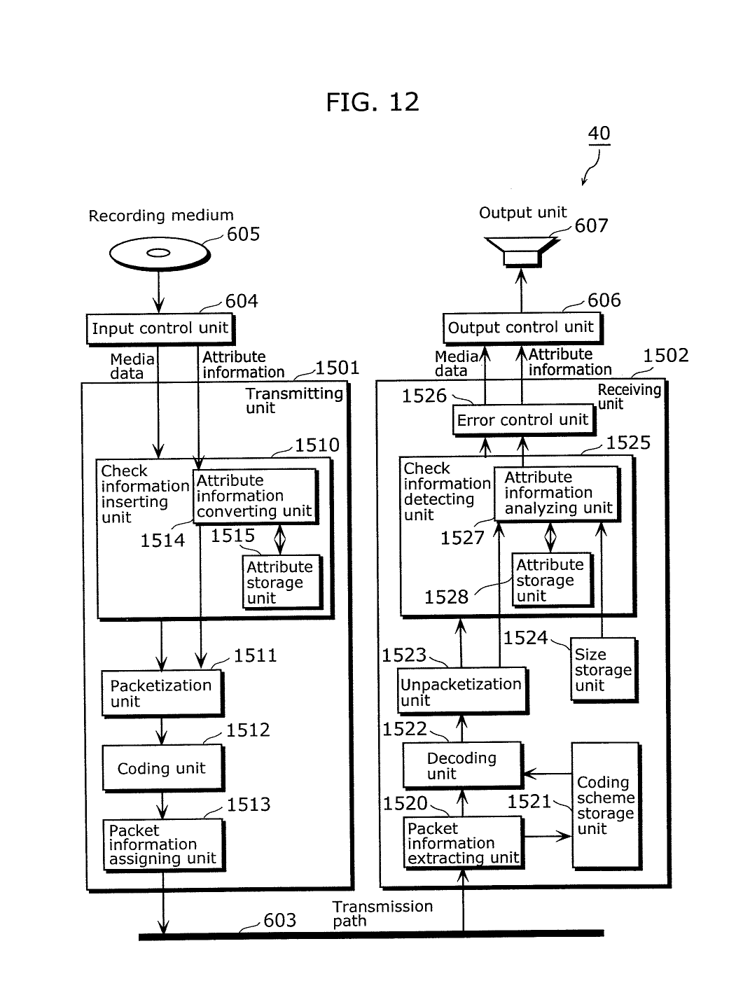

FIG. 12 is a block diagram showing the functional structure of a data transmitting apparatus 40 in this embodiment.

The data transmitting apparatus 40 includes: a transmitting unit 1501, a receiving unit 1502, a transmission path 603, an input control unit 604, a recording medium 605, an output control unit 606, and an output unit 607. It should be noted that the same structural units as those in the first to third embodiments are assigned with the same reference numerals, and the same descriptions are not repeated here.

This embodiment describes that the media data stored in the recording medium 605 is read through the input control unit 604, and the read media data is inputted to the transmitting unit 1501.

The transmitting unit 1501 processes the media data and attribute information inputted through the transmitting unit 1501 and transmits them to the transmission path 603. The receiving unit 1502 receives the data transmitted through the transmission path 603, reconstructs the data into the original media data and attribute information, performs error detection on these data and information, and output them to the output control unit 606. The output control unit 606 receives inputs of the media data outputted through the receiving unit 1502, converts them into data which can be outputted through the output unit 607, and output them.

The transmitting unit 1501 includes: a check information inserting unit 1510, a packetization unit 1511, a coding unit 1512, and a packet information assigning unit 1513.

The check information inserting unit 1510 performs data conversion for error check on the media data and attribute information inputted to the transmitting unit 1501. Subsequently, the packetization unit 1511 packetizes the data into packets, and the coding unit 1512 codes the packets.

Subsequently, the packetization information assigning unit 1513 assigns the packets control information of the packets, and outputs the packets to the transmission path 603.

The receiving unit 1502 includes: a packet information extracting unit 1520, a coding scheme storage unit 1521, a decoding unit 1522, an unpacketization unit 1523, a size storage unit 1524, a check information detecting unit 1525, and an error control unit 1526.

The receiving unit 1502 receives the data through the transmission path 603. The packet information extracting unit 1520 extracts the packet information from the packets. The packet information is stored in the coding scheme storage unit 1521. The packets from which the packet information has been extracted are inputted into the decoding unit 1522. The decoding unit 1522 decodes the packets according to the information stored in the coding scheme storage unit 1521. Subsequently, the unpacketization unit 1523 separates the packets into frames and the attribute information. The frames and attribute information are inputted to the check information detecting unit 1525. The check information detecting unit 1525 performs error detection on the frames and attribute information, and output them to the error control unit 1526. At this time, the check information detecting unit 1525 performs error detection on them based on packet size information indicating the target range for the error detection stored in the size storage unit 1524. The error control unit 1526 controls output of the media data according to error detection information obtained through the check information detecting unit 1525.

In this embodiment, the media data which is inputted to the transmitting unit 1501 has the same format as that of the data 120 in FIG. 2A. The media data is music data having a 2-channel PCM format in which a left frame (Frame L) and a right frame (Frame R) are arranged alternately. The bit length of each frame is 16 bits, and the least significant bit (LSB) of a frame and the most significant bit (MSB) of the next frame are consecutive.

The check information inserting unit 1510 includes an attribute information converting unit 1514 and an attribute storage unit 1515.

The attribute information converting unit 1514 detects a change in attribute information, and inserts an attribute information sequence for replacement according to a predetermined rule. The attribute information converting unit 1514 converts the attribute information so that a receiving-side apparatus can perform error detection on the attribute information inputted through the input control unit 604. The attribute storage unit 1515 is a unit for storing the immediately-preceding attribute information, and is necessary for allowing the attribute information converting unit 1514 to detect a change in the attribute information.

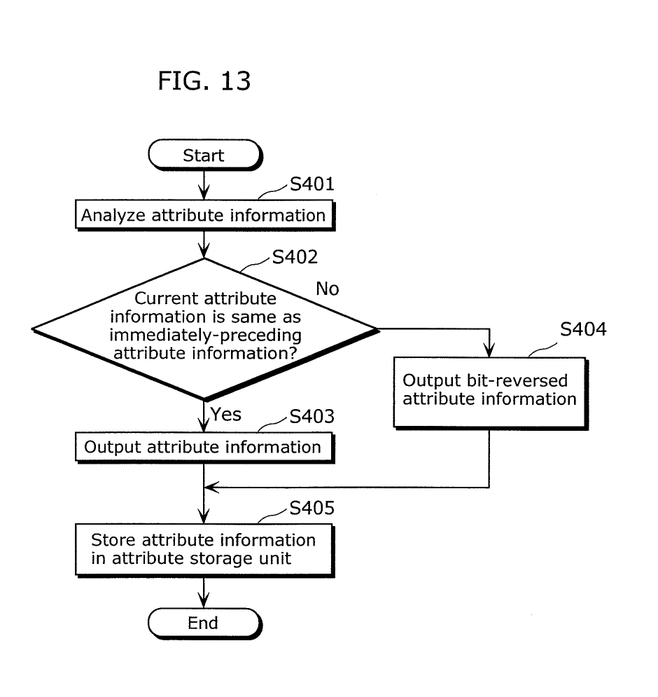

FIG. 13 is a flowchart showing processes performed in the attribute information converting unit 1514 in this embodiment.

It should be noted here that the whole attribute information of all the packets has a meaning. The processes in this flowchart are performed on each of the packets packetized by the packetization unit 1511.

The attribute information converting unit 1514 compares the attribute information of a current packet and the attribute information of the immediately-preceding packet (Step Step S401) first. In the case where the former matches the latter (Yes in Step S402), the attribute information converting unit 1514 judges that there is no change in the attribute information, and a transition to Step S403 is made. In the opposite case where the former does not match the latter (No in Step S402), the attribute information converting unit 1514 judges that there is a change in the attribute information, and a transition to Step S404 is made.

In the case where there is a change in the attribute information (No in Step S402), the attribute information converting unit 1514 outputs a bit-reversed value of the current attribute information to the packetization unit as the attribute information 1511 (Step S404).

In the opposite case where there in no change in the attribute information (Yes in Step S402), the attribute information converting unit 1514 outputs the current attribute information to the packetization unit 1511 without reversing the bit of the attribute information.

Lastly, the attribute information converting unit 1514 stores the current attribute information in the attribute information storage unit 1515 (Step S405). Here, even when the bit of the attribute information is reversed in Step S404, the original value before the reversion is stored. It should be noted that the attribute information stored in the attribute information storage unit 1515 is used as the immediately-preceding attribute information when this processing is executed next.

As describe above, in the case where there is a change in the attribute information of the packet to be transmitted, it is possible to insert, into a change point of the attribute information and the points immediately preceding and following the change point, an attribute information sequence including the attribute information to be changed, the bit-reversed value of the changed attribute information, and the changed attribute information which are transmitted in this sequence.

The packetization unit 1511 receives inputs of the frames and the attribute information, and packetizes them into a packet according to the predetermined rule.

In this embodiment, the frames and the attribute information converted by the check information inserting unit 1510 are arranged in form of the frame 140 in FIG. 3, several pairs of such frames and the attribute information are grouped to structure a packet having the same form as that of the packet 150 in FIG. 3. Otherwise, the several pairs of such frames and the attribute information may be grouped to structure a packet having the same form as that of the packet 160.

The coding unit 1512 performs data conversion such as coding and encrypting on data to be transmitted through the transmission path 603. In the case where the coding unit 1512 codes inputted data whose size does not match the coding block size predetermined as the size of a unit to be coded, the coding unit 1512 combines or separates the data in order to code the inputted data on a coding block size basis.

In this embodiment, first, packet data is segmented into coding blocks having the same predetermined coding block size as that of the packet 150 or the packet 160 in FIG. 3. As the next step, the packet data is coded on a coding block size basis.

The packet information assigning unit 1513 assigns packet information to the packets coded by the preceding coding unit 1512. Here, “packet information” indicates the positions of the boundaries between packets and the coding schemes of the packets. The packet boundary positions are used for recognizing the portions corresponding to the packets in the data received by the receiving-side apparatus. The coding schemes are information for allowing a receiving-side apparatus to recognize the coding schemes of the packets. The receiving-side apparatus can decode the packets properly by decoding them according to the specified formats. Packet information is used for making it difficult to intercept the data on the transmission path 603. For example, the coding schemes of packets are changed according to time, or the encryption keys for packets are changed in the case where these packets are encrypted.

The packets assigned with packet information by the packet information assigning unit 1513 are transmitted to the transmission path 603.

The coded data transmitted through the transmission path 603 and received by the receiving unit 1502 is inputted to the packet information extracting unit 1520 first.

The packet information extracting unit 1520 extracts the packets by extracting the packet information from the received data, and stores the coding schemes of the packets extracted from the packet information in the coding scheme storage unit 1521.

The coding scheme storage unit 1521 is a recording device such as a RAM for storing the coding schemes extracted from the packet information extracted by the packetization information extracting unit 1520.

The decoding unit 1522 decodes the data inputted through the packet information extracting unit 1520, according to the coding schemes stored in the coding scheme storage unit 1521. Since the coding schemes stored in the coding scheme storage unit 1521 are determined on a packet-by-packet basis, the decoding unit 1522 applies, in the decoding, the same coding schemes to the respective packets each of which includes several coded blocks.

The unpacketization unit 1523 separates the frames and the attribute information respectively from the packets inputted through the decoding unit 1522. The separated frames and attribute information are passed to the check information detecting unit 1525.

The size storage unit 1524 is for storing packet size information and coding block sizes to be used by this apparatus. The packet sizes and coding block sizes shown in this information match those of the packets to be transmitted.

The check information detecting unit 1525 detects whether or not an error has occurred in the transmission data, based on the frames and attribute information inputted through the unpacketization unit 1523 and the size information inputted through the size storage unit 1524. The check information detecting unit 1525 includes: an attribute information analyzing unit 1527 and an attribute storage unit 1528.

The attribute information analyzing unit 1527 analyzes whether or not the received attribute information sequence is valid, based on the frames and attribute information inputted through the unpacketization unit 1523 and the packet size information inputted through the size storage unit 1524. This apparatus judges the validity of the sequence of attribute information of a current packet and the immediately-preceding packet by comparing the attribute information of these packets.

The attribute storage information 1528 is used for storing the attribute information of the immediately-preceding packet so that the attribute information analyzing unit 1527 can check the validity of the sequence of attribute information of the current packet and the immediately-preceding packet.

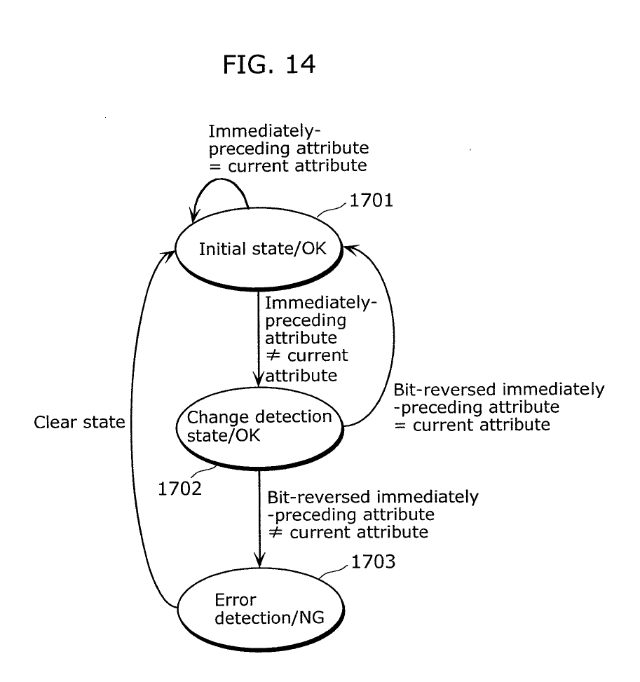

FIG. 14 is a diagram of the state transitions at the time when an attribute information analyzing unit 1527 performs error detection. Here, that the attribute information corresponding to a packet has received based on the packet size information obtained through the size storage unit 1524 triggers that the comparison between the attribute information of the current packet and the attribute information of the immediately-preceding packet is made, and that the state transition according to the result of the comparison is made. A judgment of “OK” or “NO” shows the error state of the packet immediately preceding a current packet.

A state 1701 shows the initial state. This state shows that the attribute information is constant, and that no error has been detected in the immediately-preceding packet. A return to the state 1701 is made in the case where a packet is received and the attribute information of the current packet matches the attribute information of the immediately-preceding packet, and a judgment that the immediately-preceding packet is normal is made at this time. In the case where the attribute information of the current packet does not match the attribute information of the immediately-preceding packet, a transition to a state 1702 is made. In this case, a change from a state where attribute information is constant is detected, and thus the packet before the current packet is judged to be normal.

A state 1702 shows a change detection state. This state shows that the immediately-preceding attribute information has been changed although the previous comparison showed that the attribute information was constant. It is unknown whether the state shows a sequence inserted in Step S404 in FIG. 13 or a damage in the attribute information caused by a transmission error. Either the sequence or the damage is determined according to the attribute information of the packets received in this state.

In this state, in the case where a packet is received and the attribute information of the current packet matches the bit-reversed attribute information of the immediately-preceding packet, this match can show the sequence of attribute information inserted in Step S404, and a transition to the state 701 is made. At this time, the immediately-preceding packet can be judged to be normal, and the value of the packet is the same as the bit-reversed attribute information of the immediately-preceding packet (that is, the attribute information of the current packet). In the case where the attribute information of the current packet does not match the bit-reversed attribute information of the immediately-preceding packet, a judgment that an error has occurred in the attribute information is made, and a transition to the state 1703 is made. At this time, the immediately-preceding packet is judged as having an error.

It should be noted that the attribute information outputted through the check information detecting unit 1525 is bit-reversed at the change point by the attribute information converting unit 1514, and thus it is possible to reconstruct the original attribute information by bit-reversing the attribute information and passing it to the error control unit 1526.

A state 1703 shows an error detection state. In this state, no state transition is made except that a return to the state 1701 is made according to a trigger to clear the state. In the case where this state is entered, there is a need to solve the cause of the transmission error, and initialize the state according to the trigger to clear the state.

The error control unit 1526 associates the frames with the error detection information outputted through the check information detecting unit 1525, and performs a mute processing on the frames judged as having the error so that sound resulting from the frame are not outputted through the output control unit 606. For example, it is possible to reduce noises by repeatedly outputting the normal frame located immediately before the abnormal frame instead of the abnormal frame.

The attribute information outputted through the check information detecting unit 1525 can also be associated with the error detection information. For example, in the case where an error has occurred in a frame included in a packet, it is possible to notify the system of an error by using the attribute information of the frame included in the packet or to prevent the current attribute information from being overwritten with the abnormal attribute information.

The error detection information notified by the check information detecting unit 1525 shows the error state of the immediately-preceding packet. Thus, a mounted buffer has a capacity large enough to hold output data necessary for performing error control on the data judged as having the error by the error control unit 1526.

The output control unit 606 performs digital-to-analog conversion, amplification and the like on the media data outputted through the error control unit 1526 and stores attribute information, so that the succeeding output unit 607 can refer to the attribute information as necessary and reproduce the media data outputted through the error control unit 1526.

The following describe operations performed in the case where an attribute information sequence is normal.

First, the media data and the attribute information outputted through the input control unit 604 are inputted to the transmitting unit 1501. Here, it is assumed that the attribute information inputted to the transmitting unit 1501 is changed from A to B. Subsequently, the attribute information converting unit 1514 converts the attribute information, and inserts an attribute information character for replacement.

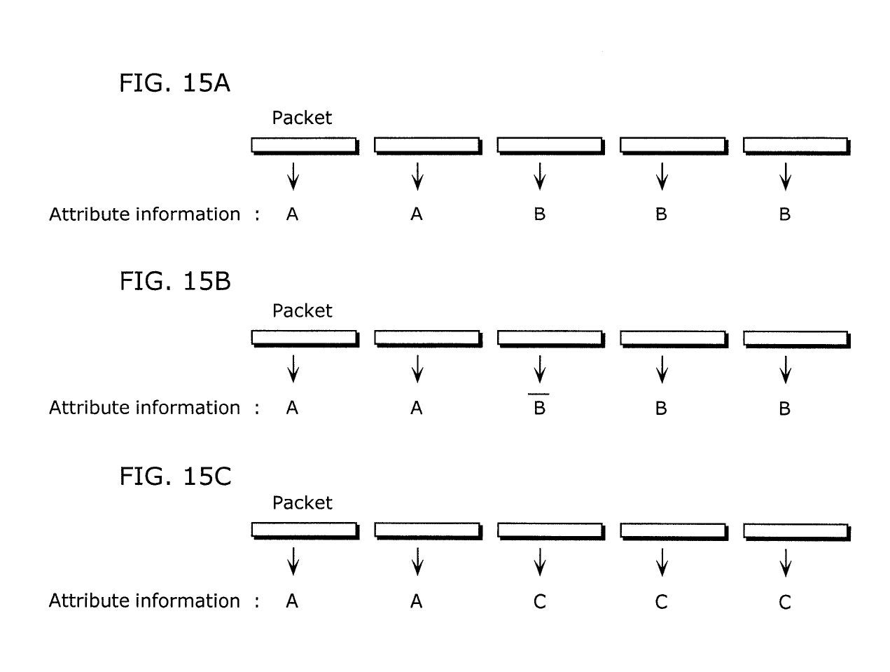

FIGS. 15A to 15C are diagrams each of which shows an example of the association between packets and the attribute information. The packets shown in FIGS. 15A to 15C are some of the packets in a packet sequence which are being transmitted continuously.

FIG. 15A shows a state changing from A to B at a certain time point (the third packet here) in the attribute information, and this sequence of packets is inputted to the transmitting unit 1501.

FIG. 15B shows the state entered after the attribute information converting unit 1514 processes the attribute information in FIG. 15A by inserting an attribute information character for replacement. According to the procedure in FIG. 13, the attribute information of the third packet which is the change point of the attribute information is changed from “B” to “−B”.

The data outputted through check information inserting unit 1510 is packetized by the packetization unit 1511, and the packets are coded by the coding unit 1512. It is assumed that the coding unit 1512 encrypts the packets in the coding.

The packet information assigning unit 1513 assigns packet information to the encrypted data, and outputs the data to the transmission path 603. Here, the encryption key used as packet information in the encryption is assigned as the coding scheme. The data is inputted to the receiving unit 1502 through the transmission path 603. The packet information extracting unit 1520 extracts the packet information from the data. The coding scheme of the data is stored in the coding scheme storage unit 1521.

The decoding unit 1522 decodes the coded packets based on the information obtained through the packet information extracting unit 1520 and the coding scheme storage unit 1521. The decoding makes it possible to obtain the same result as in FIG. 15B.

The unpacketization unit 1523 separates the data into frames and the attribute information. The attribute information analyzing unit 1527 performs error detection on each attribute information in the attribute information sequence by analyzing it.

When the attribute information analyzing unit 1527 performs error detection on each attribute information in the attribute information sequence, the state 1301 is shown at the first and second packets, the state 1302 is entered at the third packet, and a return to the state 1301 is made at the fourth packet because the current attribute information matches the immediately-preceding bit-reversed attribute information. At this time, the sequence of packets is judged to be normal.

The following describe operations performed in the case where an attribute information sequence is abnormal.

First, the media data and the attribute information outputted through the input control unit 604 are inputted to the transmitting unit 1501. Here, it is assumed that the attribute information inputted to the transmitting unit 1501 does not change, and that the attribute information outputted through the attribute information converting unit 1514 is always constant within the range described below. Subsequently, the attribute information converting unit 1514 converts the attribute information, and inserts an attribute information character for replacement.

The data outputted through check information inserting unit 1510 is packetized by the packetization unit 1511, and the packets are coded by the coding unit 1512. Here, it is assumed that the coding unit 1512 performs encryption in the coding of the packets. For example, it is assumed here that the encryption key data is deformed during the transmission or the coding scheme information within the packet information is deformed because of the causes such that the encryption key is overwritten by noises coming from outside or due to overrun of the control device. These causes result in an improper decoding of the data in which abnormal encryption key is used. In this case, the attribute information and frames which should not have been changed become abnormal because the decryption key is different from the encryption key. Furthermore, the frames subsequent to the deformed data may be constantly judged to be abnormal in the case where this error cannot be detected, which causes a serious problem that noises continue for a long time.

The packet information assigning unit 1513 assigns packet information to the data encrypted using the deformed encryption key, and outputs it to the transmission path 603. The data is inputted to the receiving unit 1502 through the transmission path 603. The packet information extracting unit 1520 extracts packet information from the data. The coding scheme of the data is stored in the coding scheme storage unit 1521.

The decoding unit 1522 decodes the packets coded based on the information obtained through the packet information extracting unit 1520 and the coding scheme storage unit 1521. However, the decoded data is different from the original data because the decryption key used by the decoding unit 1522 is different from the encryption key used by the coding unit 1512. It is assumed that the frames and attribute information included in the packets decoded using the decryption key different from the encryption key used in the coding have values different from those of the original data.

The unpacketization unit 1523 separates the data into frames and the attribute information. The attribute information analyzing unit 1527 performs error detection on each attribute information in the attribute information sequence by analyzing it. In the case where the data in the respective coding blocks are the same and the data is encrypted using the same encryption key data, the resulting decoded data of the respective coded blocks shows the same values. For this reason, the constant attribute information of data is transmitted. However, in the case of an occurrence of an error assumed such that an encryption key is changed to another encryption key in the transmission of the data, the attribute information is different between before and after the change of the encryption keys while the attribute information before the change is constant and the attribute information after the change is constant. This state is frequently occurs especially when a packet 160 is used.

FIG. 15C shows the association between the decoded packets and the attribute information in the case of the occurrence of an error such that the encryption keys are changed after constant attribute information is transmitted.

FIG. 15C shows that the encryption keys are changed at the third packet, and shows that the attribute information of each of the subsequent packets is changed to “C” although the attribute information is constant and each of the packets should have shown “A”.

The following describes a case where the attribute information analyzing unit 1527 performs error detection on such data. The first and second packets having the same encryption key data show the state 1701. The third packet which is the first packet having the mismatching encryption key data shows the state 1702. The forth packet shows the state 1703 because the current attribute information does not match the bit-reversed value of the immediately-preceding information. In this case, the third packet is judged as having an error.

Since the third packet is judged as having the error by the attribute information analyzing unit 1527, the error control unit 1526 performs a mute processing on the frames corresponding to the size of the abnormal packet. In addition, the attribute information of the packets including the abnormal frames is also recognized as abnormal.

Bit reverse is used as an information conversion scheme in the insertion of an attribute information character in this embodiment, but it should be noted that another reversible scheme such as operations using the complement number of 2, −1 or +1 may be used instead.

The attribute information of the packet at which the attribute information is changed is converted in the insertion of an attribute information character in this embodiment, but it should be noted that the attribute information of the packet located immediately before the packet at which the attribute information is changed may be converted.

As described above, the data transmitting apparatus 40 of this embodiment makes it is possible to reduce noises generated due to a transmission error caused on the transmission path 603 using the simple circuit and control procedure without deteriorating the sound quality and unnecessarily occupying the transmission band. The data transmitting apparatus can detect damage in packet information without assigning error check codes to data, such as packet information, important in the data transmission, perform noise reduction control, and detect damage in attribute information.

Furthermore, the data transmitting apparatus 40 makes it possible to prevent occurrence of a serious problem that encryption key data is deformed in the transmission due to the cause that the encryption key data is overwritten by noises coming from outside or due to overrun of the control device, resulting in noises.

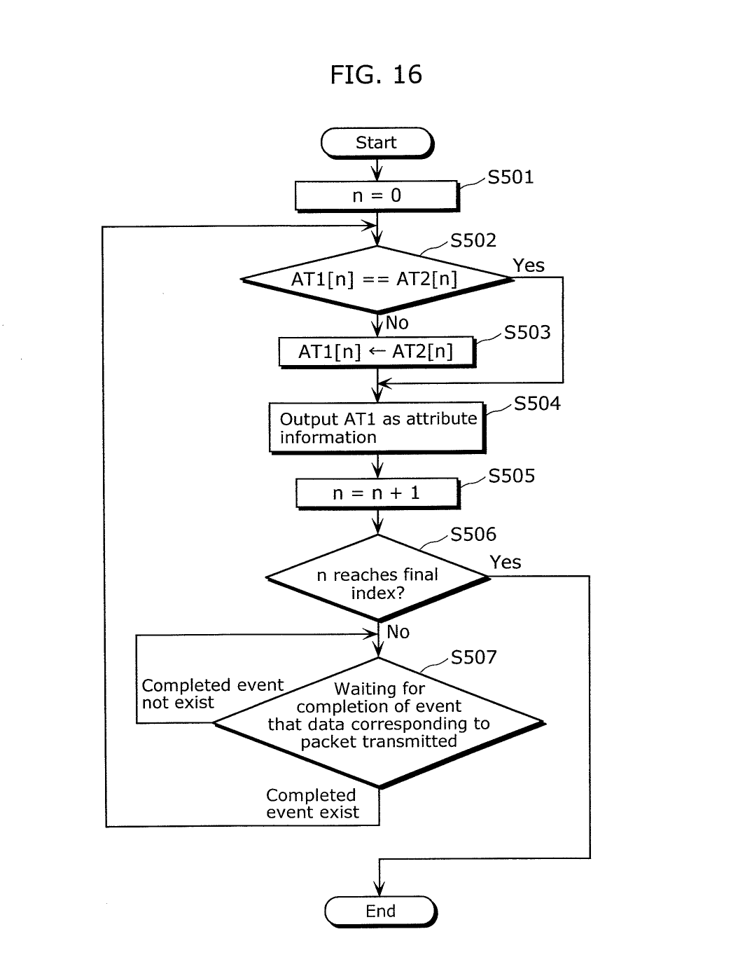

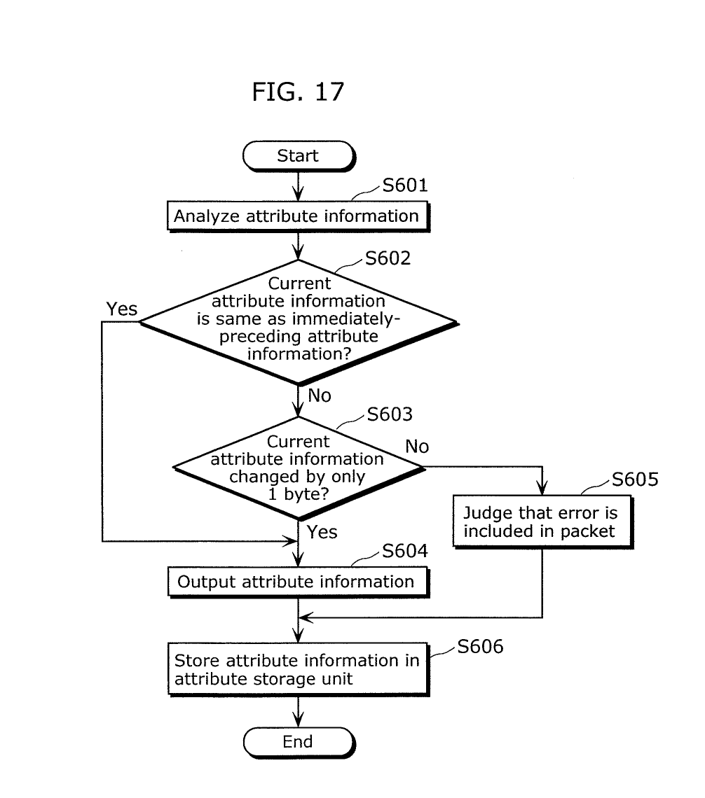

FIG. 16 is a flowchart showing a variation of an attribute information inserting procedure performed by the attribute information converting unit 1514 in this embodiment. In addition, FIG. 17 is a flowchart showing an error detection procedure performed by the attribute information analyzing unit 1127 in this variation.

First, FIG. 16 is described.

Here, a change in the attribute information inputted through the input control unit 604 triggers the execution of the following processes.

First, the initialization processing of a variable n is executed (Step S501). This variable shows the position of the attribute information to be processed.

Next, the attribute information after the change is compared with the attribute information before the change, and a judgment is made based on the comparison (Step S502). Here, AT1 shows the attribute information before the change, and AT2 shows the attribute information after the change. The attribute information is structured with several pieces of information, and the attribute information relating to the positions represented as variables n are compared in this processing.

In the case where the comparison of the attribute information does not indicate a match (No in Step S502), it is judged that there is a change in the attribute information, and a transition to Step S503 is made. In the opposite case where the comparison of the attribute information indicates a match (Yes in Step S502), it is judged that there is no change in the attribute information, and a transition to Step S504 is made. According to the judgment made in Step S503, the attribute information relating to the position represented as a variable n is updated to the attribute information after the change.

Step S504 indicates an output processing of the attribute information. The whole AT1 holding the attribute information before the change is outputted to the packetization unit 1511. In the case where the attribute information has been updated in Step S503, the AT1 to be outputted is updated from the attribute information outputted immediately before.

Step S505 indicates an addition processing of the variable n. The position of the attribute information to be processed is changed by incrementing the variable n by 1.

Step S506 indicates a processing for judging whether or not all pieces of the attribute information have been processed after the change in the attribute information. In the case where the variable n reaches the upper limit of AT1 by the increments in Step S505, it is judged that the update of the attribute information is completed, which completes this procedure. Otherwise, it is judged that there remains attribute information to be processed, and a transition to Step S507 is made. After the completion of this procedure, the processes starting with Step S501 are restarted triggered by the change in the attribute information to be inputted.

Step S507 is a processing for waiting for an event that the data corresponding to a packet has been transmitted. This processing is necessary for updating a unit of the attribute information of a packet. It is assumed here a completion event indicates whether or not the frames in the packet obtained through the input control unit 604 have been inputted, and this procedure is stopped until the completion event occurs. When the completion event occurs, the processes are restarted with Step S502.

According to the procedure, it is possible to update a unit of the attribute information and output the attribute information with the updated unit in each packet in the case where there is a change in the attribute information obtained through the input control unit 604.

It is only necessary that the attribute information before and after the change are compared partly according to the procedure, which reduces the amount of operation. More specifically, it is only necessary that the processes from Steps S502 to S507 are executed by the time that the transmission of a packet is completed. This shows that the procedure can be executed using software in a comparatively slow CPU because it requires only a small processing load, and thus it does not affect the execution of other tasks even when the CPU is processing multiple tasks in parallel.

First, FIG. 17 is described.

The following processes are executed on a packet-by-packet basis.

First, the attribute information analyzing unit 1127 analyzes attribute information (Step S601). Next, the attribute information analyzing unit 1127 compares the attribute information of a current packet with the attribute information of the immediately-preceding packet stored in the attribute storage unit 1528, and in the case where the comparison indicates a match (Yes in Step S602), it is judged that there is no change in the attribute information, and a transition to Step S604 is made. In the opposite case where the comparison indicates a mismatch (No in Step S602), it is judged that the attribute information has been updated or the packet includes an error, and a transition to Step S603 is made.

Step S603 indicates a processing for judging whether or not an attribute information sequence is valid. In the case where the attribute information of the current packet is compared with the attribute information of the immediately-preceding packet, and the comparison shows that only a single unit of the attribute information of the current packet is changed, it is judged that this change shows that the attribute information sequence is the attribute information sequence inserted by the attribute information converting unit 1514, and a transition to Step S604 is made. In the case where the comparison indicates that two or more units of the attribute information are changed, it is judged that there is a violation of the attribute information sequence rule, and a transition to Step S605 is made.

In this embodiment, it is assumed that the unit of the attribute information corresponds to 1 byte.

Step S605 shows an error judgment processing. In the case where an abnormal packet is received, the fact is notified to the error control unit 1526. The judgment that there is a violation of the attribute information sequence rule triggers the execution of this processing.

Step S604 indicates an output processing of the attribute information. The attribute information analyzing unit 1127 notifies the error control unit 1526 of the fact that a current packet is normal, and then the attribute information of the packet is outputted. This process is executed when the attribute information sequence of a current packet is judged to be normal.

Step S606 is a process for storing the attribute information of the current packet. The attribute information of the current packet is stored in the attribute storage unit 1528 so that error detection can be performed on the next packet. This process completes the procedure.

The following describe operations performed in the case where an attribute information sequence is normal. Here, it is assumed that the attribute information of a packet is represented in 4 bytes.

First, the media data and the attribute information outputted through the input control unit 604 are inputted to the transmitting unit 1501. Here, the attribute information to be inputted to the transmitting unit 1501 is “abcd” first, and then changed to “efgh”.

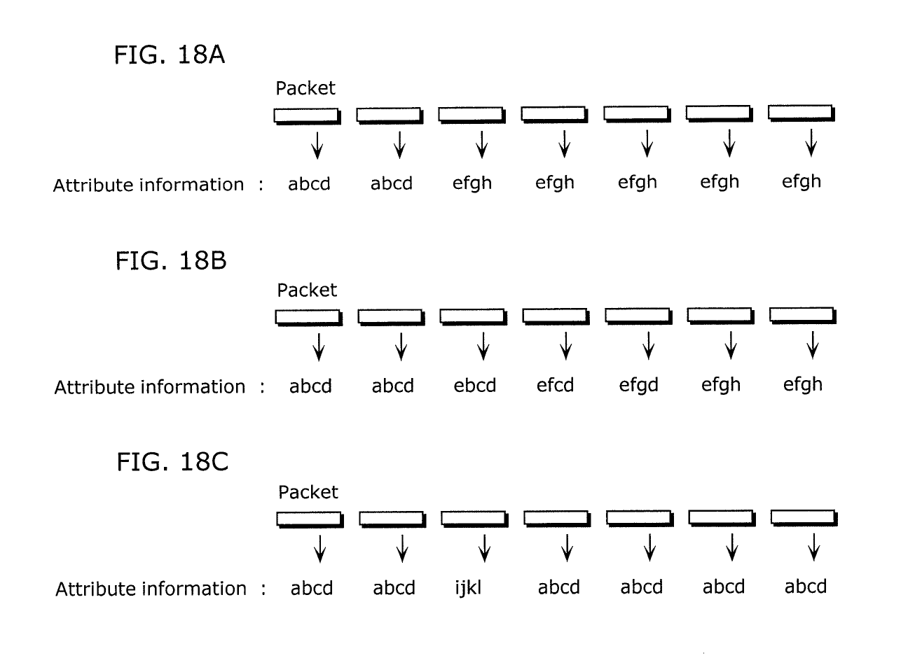

FIGS. 18A and 18C are diagrams each of which shows an example of packets and the attribute information. The packets shown in FIGS. 18A to 18C are some of the packets in a packet sequence which are being transmitted continuously.

FIG. 18A shows the association between the packets which are outputted to the transmission path 603 and the attribute information assuming that no attribute information sequence is not inserted by the attribute information converting unit 1514. At the third packet among the seven packets shown in the diagram, the attribute information is changed from “abcd” to “efgh”.

FIG. 18B shows the association between the packets and the attribute information. The packets include an attribute information sequence inserted by the attribute information converting unit 1514 and have been outputted to the transmission path 603. The attribute information converting unit 1514 changes the attribute information of the third packet by 1 byte from “abcd” to “ebcd” according to the procedure in FIG. 16. The attribute information of the fifth packet is also changed by 1 byte from that of the fourth packet, and the attribute information of the sixth packet is changed to “efgh”.

The data outputted through check information inserting unit 1510 is packetized by the packetization unit 1511, and the packets are coded by the coding unit 1512. The packet information assigning unit 1513 assigns packet information to the coded data, and outputs the coded data with packet information to the transmission path 603.

The packet information extracting unit 1520 extracts the packet information from the packets inputted to the receiving unit 1502 through the transmission path 603. The coding schemes of the packets are stored in the coding scheme storage unit 1521.

The decoding unit 1522 decodes the packets coded based on the information obtained through the packet information extracting unit 1520 and the coding scheme storage unit 1521. The unpacketization unit 1523 separates the frames and the attribute information. The attribute information analyzing unit 1527 performs error detection on each attribute information in the attribute information sequence by analyzing it.

In the case where the attribute information analyzing unit 1127 performs error detection on the data shown in FIG. 18B, the received first and second packets are judged to be normal (as having the same attribute information) in Step S602 in FIG. 17. The attribute information of the third, fourth, fifth and sixth packets is changed by 1 byte between any of the adjacent packets, and thus these packets are judged to be normal in Step S602 in FIG. 17. The seventh packet is also judged to be normal as having the same attribute information, resulting in the judgment that the attribute information sequence is normal.

The following describe operations performed in the case where an attribute information sequence is abnormal.

First, the media data and the attribute information outputted through the input control unit 604 are inputted to the transmitting unit 1501. Here, it is assumed that the attribute information inputted to the transmitting unit 1501 does not change, and that the attribute information outputted through the attribute information converting unit 1514 is always constant within the range described below.

The frames and the attribute information are packetized by the packetization unit 1511, and coded by the coding unit 1512. The packet information assigning unit 1513 assigns packet information to the coded data, and outputs the coded data with packet information to the transmission path 603. Here, it is assumed that a portion of a packet is deformed due to a transmission error on the transmission path 603. The packet information extracting unit 1520 extracts the packet information from the packets inputted to the receiving unit 1502 through the transmission path 603. The coding schemes of the packets are stored in the coding scheme storage unit 1521.

The decoding unit 1522 decodes the coded packets based on the information obtained through the packet information extracting unit 1520 and the coding scheme storage unit 1521. However, the coded data is different from the original data because the data has been damaged on the transmission path 603.

FIG. 18C shows the association between the decoded packets and the attribute information. The attribute information of the transmitted data is constant as “abcd”, and thus the attribute information of the decoded data should be “abcd”. However, the attribute information of the third packet is changed to “ijkl”. It is assumed that all the data of the frames and attribute information of the damaged decoded packets have values different from those of the original data.

The unpacketization unit 1523 separates the data into frames and the attribute information. The attribute information analyzing unit 1527 performs error detection on each attribute information in the attribute information sequence by analyzing it.

In the case where the attribute information analyzing unit 1527 performs error detection on the data in FIG. 18C, the received first and second packets are judged to be normal as having the attribute information which matches the attribute information of an immediately-preceding packet. Here, the attribute information of the third packet is different from the attribute information of the second packet by more than 2 bytes. Thus the third packet is judged as having an error in Step S603 in FIG. 17.

Since the packet has been judged as having the error by the attribute information analyzing unit 1527 as described above, the error control unit 1526 performs a mute processing on the frames included in the current packet. In addition, the attribute information of the current packet is judged as having the error. Since error detection is performed by checking the attribute information on a 1-byte by 1-byte basis, it is possible to detect most of errors such as deformation of encryption key data caused in the transmission because it is highly likely that such deformation results in changes in the attribute information of the whole packet.

It is assumed that the attribute information is changed on a 1-byte basis in this embodiment, but it should be noted that the check information detecting unit 1525 may perform error detection on the attribute information for each predetermined unit having another value such as 2 bytes.

As described above, the data transmitting apparatus according to this embodiment with a simple circuit for executing a simple error control procedure makes it possible to reduce noises without deteriorating sound quality caused by transmission errors generated on a transmission path and without occupying an unnecessary transmission bandwidth. The data transmitting apparatus can detect damage in packet information without assigning error check codes to data such as packet information important in the data transmission, perform noise reduction control, and detect damage in attribute information.

Furthermore, the data transmitting apparatus 40 makes it possible to prevent occurrence of a serious problem that encryption key data is deformed in the transmission due to the cause that the encryption key data is overwritten by noises coming from outside or due to overrun of the control device, resulting in noises.

The attribute information sequence inserting procedure in FIG. 16 requires only a small amount of attribute information to be processed at a time, and makes it easier for a CPU to execute the procedure using software. Since it is possible to perform error detection based on a packet currently being received, not based on the packet received immediately before, it is possible to save a storage area for storing the immediately-preceding packet for error control.

### Fifth Embodiment

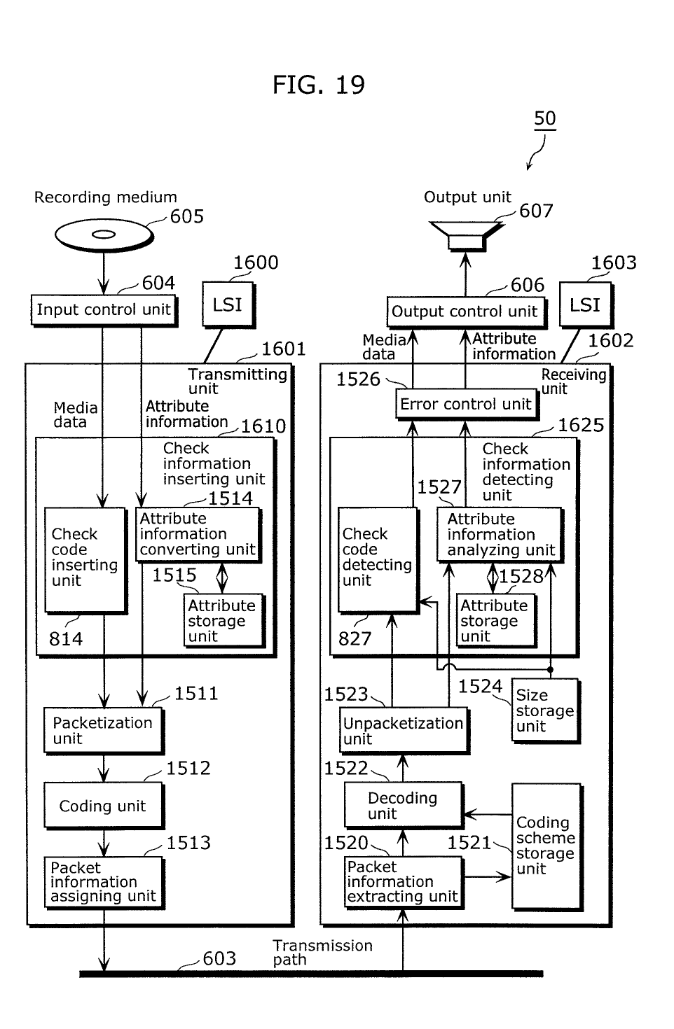

FIG. 19 is a block diagram showing the functional structure of a data transmitting apparatus 50 in this embodiment.

The data transmitting apparatus 50 includes: a transmitting unit 1601, a receiving unit 1602, a transmission path 603, an input control unit 604, a recording medium 605, an output control unit 606, and an output unit 607. It should be noted that the same structural units as those in the first to fourth embodiments are assigned with the same reference numerals, and the same descriptions are not repeated here.

Since the data transmitting apparatus 50 is obtained by combining the data transmitting apparatuses in the first to fourth embodiments, the same descriptions are not repeated here.

The following describes the data transmitting apparatus 50 in this embodiment.

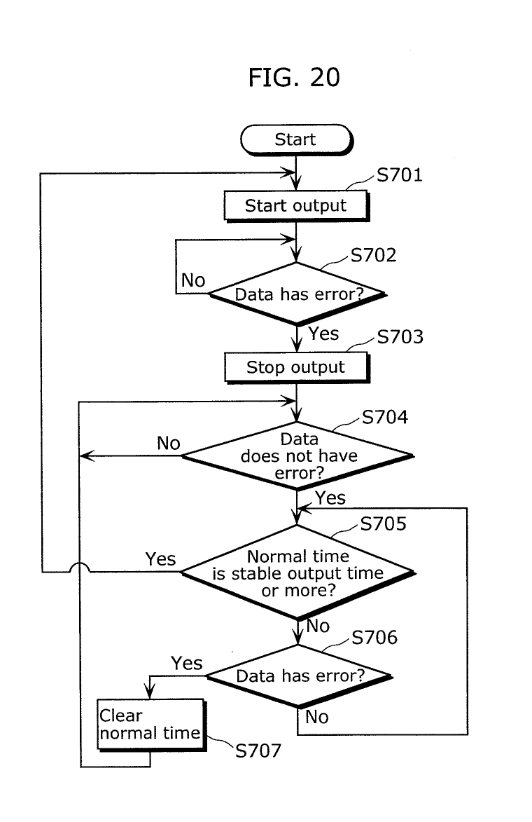

FIG. 20 shows a conventional processing performed by the error control unit 1526.

In Step S701, which is a process for starting output of data, normal data is outputted to the output control unit 606.

Step S702 shows a process for judging whether or not the data to be outputted at this time is normal. In the case where the data is normal, the data is outputted, and the error check processing for the following data in Step S702 is continued. In the case where the data is abnormal, a transition to Step S703 is made to stop the output of data.

Step S703 is a process for stopping the output of data in the case where abnormal data is detected.

Step S704 is a process for judging whether or not the next data is normal. In the case where the next data is also abnormal, error detection in Step S704 is further performed on the following data. In the case where normal data is detected, a transition to Step S705 is made.

Step S705 is a process for judging whether or not the time elapsed after the normal data is detected equals to or exceeds a predetermined stable output time. This process is performed to stop the output of data until normal data are consecutively detected for the stable output time. When normal time during which normal data are consecutively detected reaches the stable output time, a transition to Step S701 is made to restart the output of data. When normal time during which normal data are consecutively detected reaches the stable output time, the output of data is not restarted, and a transition to Step S706 is made to check whether or not current data is abnormal.

Step S706 is a process for judging whether or not the data is abnormal. When the transition to this step is made, the normal time during which normal data are consecutively detected does not reach the stable output time. In the case where the current data is normal, a transition to Step S705 is made in order to judge the normal time reaches the stable output time. In the opposite case where the current data is abnormal, a transition to Step S707 is made in order to wait for a return from an abnormal state to a normal state.

Step S707 is a process for clearing the accumulated normal time. After the clearing, a transition to Step S704 is made, and the processes starting with the process for waiting for a return from an abnormal state to a normal state are performed again.

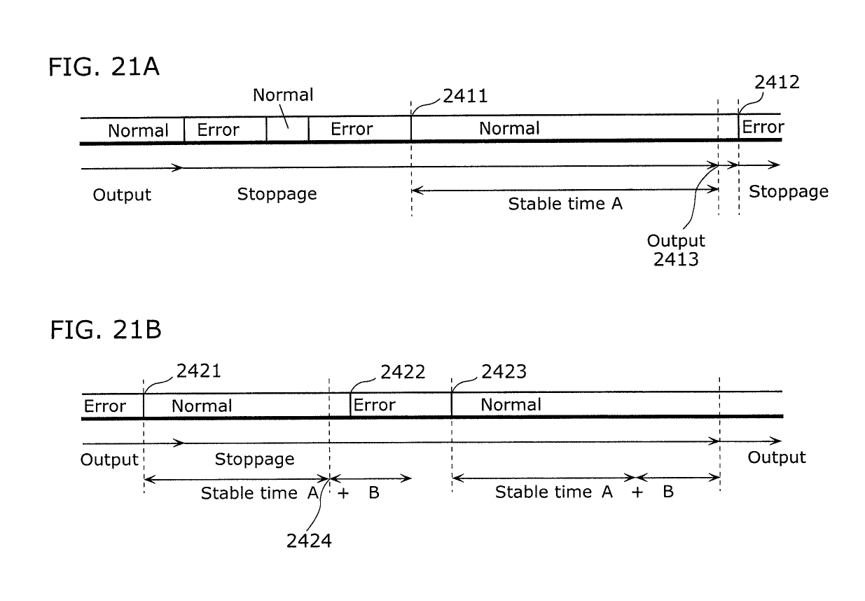

FIGS. 21A and 21B show the association between the abnormal states of data and the output states of the data in the error control unit 1526.

FIG. 21A shows a return from an abnormal state to a normal state.

FIG. 21A shows that the first data is normal, and that the data is being outputted. When abnormal data is detected later, the fact is judged in Step S702, and the output of data is stopped by the process of Step S703.

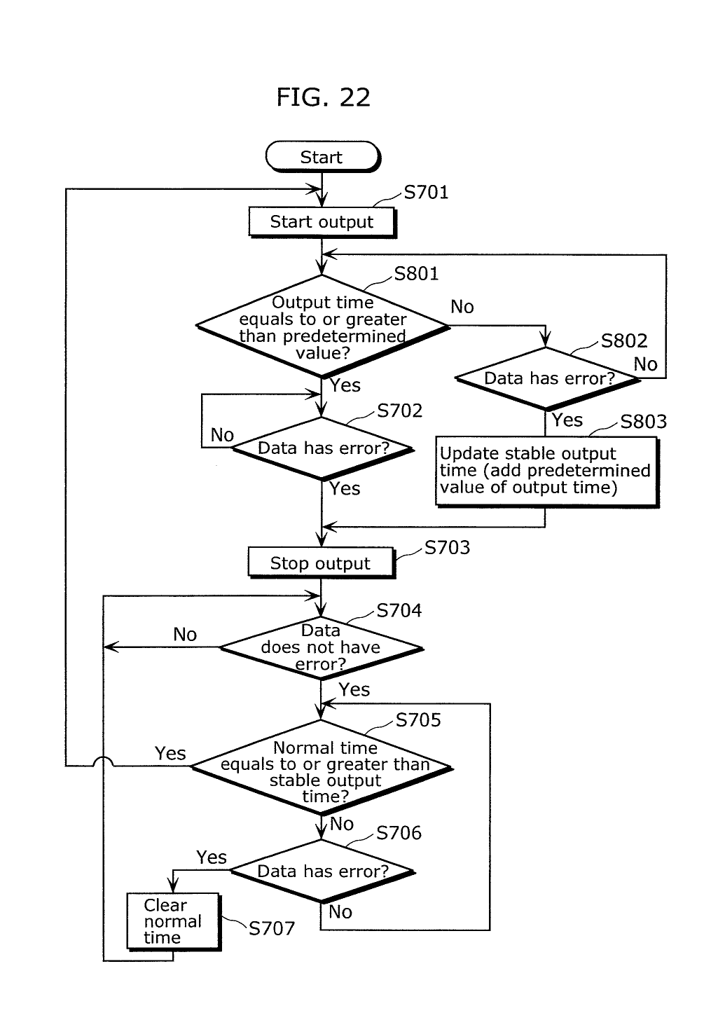

Next, normal data is detected once, but abnormal data is detected immediately after the detection of the normal data. Since an abnormal state is detected before the normal time reaches the stable output time, the data is judged to be abnormal in Step S706, and a transition to the process for waiting for a return to a normal state is made. Subsequently, normal data is detected again at time 2411, and the normal state continues to time 2412. According to the procedure below with reference to FIG. 22, a judgment on the start of output is made in Step S705 at time 2413 after stable time is elapsed from time 2411, and the output of data is restarted. Subsequently, abnormal data is detected again at time 2412, the output of data is stopped again at this time.

Here, in the case where the time from time 2413 to time 2412 during which the output of data is restarted and continued is a short period of time, the reproduced sound generated from the output data sounds like noises. It is conceivable that data error patterns depend on circumstances. For example, when a pattern shown as FIG. 21A is repeated, noises are generated repeatedly.

FIG. 22 shows processing performed by the error control unit 1526 in this embodiment. The present invention makes it possible to reduce noises by changing stable output time according to normal time histories. It should be noted that the same processes in FIG. 22 as those in FIG. 20 are assigned with the same reference numerals.

In Step S701, which is a process for starting output of data, normal data is outputted to the output control unit 606.

Step S801 is a process for judging whether or not the time elapsed after the output of data is restarted equals to or exceeds a predetermined output time. A transition to Step S702 is made in the case where the output time equals to or exceeds the predetermined output time; otherwise, a transition to Step S802 is made.

While any output time except for 0 may be set, it is effective for noise reduction to set a value for the output time which does not cause a listener to have a bad feeling when the output is stopped after the lapse of the output time.

Step 702 shows a process for judging whether or not the data to be outputted at this time is normal. Since the output time reaches the predetermined output time in the case where the transition to this step is made, the output is judged to be stable. In the case where the data is normal, the data is outputted, and the error check processing for the following data in Step S702 is continued. In the case where the data is abnormal, a transition to Step S703 is made to stop the output of data.

Step 802 shows a process for judging whether or not the data to be outputted at this time has an error. Since the output time does not reach the predetermined output time in the case where the transition to this step is made, the output is judged to be not stable enough although the output has been started. The output is continued in the case where normal data is detected in this state, and a transition is made to Step 801 where a judgment on the output time is made. In the case where abnormal data is detected, ia judgment that the abnormal data is detected before reaching the stable output time is made, and a transition to Step S803 is made.

Step S803 is a process for updating stable output time. Here, a predetermined output time is added to the stable output time, and a transition to Step S703 is made to stop the output of the abnormal data.

Step S703 is a process for stopping output of data in the case where abnormal data is detected.

Step S704 is a process for judging whether or not the next data is normal. In the case where the next data is also abnormal, error detection in Step S704 is further performed on the following data. In the case where normal data is detected, a transition to Step S705 is made.

Step S705 is a process for judging whether or not the time elapsed after the normal data is detected equals to or exceeds a predetermined stable output time. This process is performed to stop the output of data until normal data are consecutively detected for the stable output time. When normal time during which normal data are consecutively detected reaches the stable output time, a transition to Step S701 is made to restart the output of data. When normal time during which normal data are consecutively detected does not reach the stable output time, the output of data is not restarted, and a transition to Step S706 is made to check whether or not current data is abnormal.

Step S706 is a process for judging whether or not the data is abnormal. In the case where the transition to this step is made, the normal time during which normal data are consecutively detected does not reach the stable output time. In the case where the current data is normal, a transition to Step S705 is made in order to judge the normal time reaches the stable output time. In the opposite case where the current data is abnormal, a transition to Step S707 is made in order to wait for a return from a data abnormal state to a data normal state.

Step S707 is a process for clearing the accumulated normal time. After the clearing, a transition to Step S704 is made, and the processes starting with the process for waiting for a return from a data abnormal state to a data normal state are performed again.

The following describe processes in FIG. 22 performed at the time of an error.

In the case where a state shown in FIG. 21A occurs, output of data is started at time 2413 in a conventional manner. The output is started immediately after the process of Step S701 is executed. Subsequently, abnormal data is detected at time 2412. Since the output time is shorter than the predetermined output time, a judgment on whether or not the data is abnormal is made in Step S802. The stable output time is updated based on the judgment made in Step S803. When the initial value of the stable output time is “A”, and the predetermined output time is “B”, the new stable output time is obtained by adding “A” and “B”. After the completion of Step S803, the output of data is stopped again in Step S703.

FIG. 21B shows the state next to the state shown in FIG. 21A. Abnormal data is detected during the time from time 2412 to time 2421, and normal data is detected during the time from time 2421 to time 2422. This time segment is approximately the same as the time segment from time 2411 to time 2412. Subsequently, abnormal data is detected during the time from time 2422 to time 2423 again, and normal data is detected after time 2423. Time 2424 shows a time point at which the initial value A of the stable output time elapses from time 2421.

When an abnormal state is changed to a normal state at time 2421, the process of Step S705 is executed. The output of data is started at time 2424 if the data is outputted according to one of the conventional schemes where the stable output time is fixed. However, in the present invention, the output of data is stopped until time 2422 because the stable output time has been updated to the new stable output time. Since abnormal data has been detected at time 2422, the data is judged as having the error in Step S706, and a transition to Step S707 is made. The normal time accumulated up to this point is cleared, and a judgment on the stable output time starting from time 2423 at which normal data is detected is made. The output is restarted in the process of Step S701 when the new stable output time obtained by adding “A and B” elapses from time 2423.

As described above, the present invention makes it possible to reduce noises resulting from abnormal data in the circumstances where similar patterns of data errors are generated due to outside causes.

The following describe packet information extracting processes performed in this embodiment.

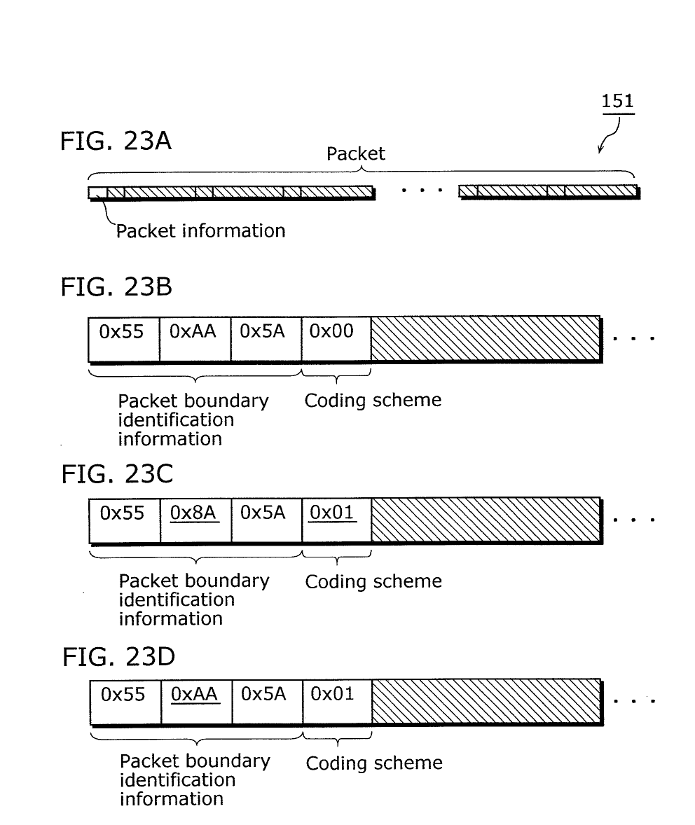

FIGS. 23A to 23D are diagrams each of which illustrates to-be-transmitted packets assigned with packet information.

FIG. 23A is a diagram showing the structure of a packet assigned with packet information. The packet information, which is not coded, is assigned to the header portion of the coded packet.

FIG. 23B shows the details of the header portion of the packet shown in FIG. 23A. FIG. 23B shows that the packet information is structured with 3-byte packet boundary identification information and 1-byte coding scheme information. A receiving-side apparatus can determine the range of the packet based on the packet boundary information.

The values representing the packet information shown in FIGS. 23A to 23D are examples, and thus other values may be used.

In the case where the packet boundary identification information of packets is damaged due to an error on a transmission path, no conventional techniques make it possible to determine the range of the packets and to process the data including the packets as normal data even when the data other than the packet boundary identification information is normal.

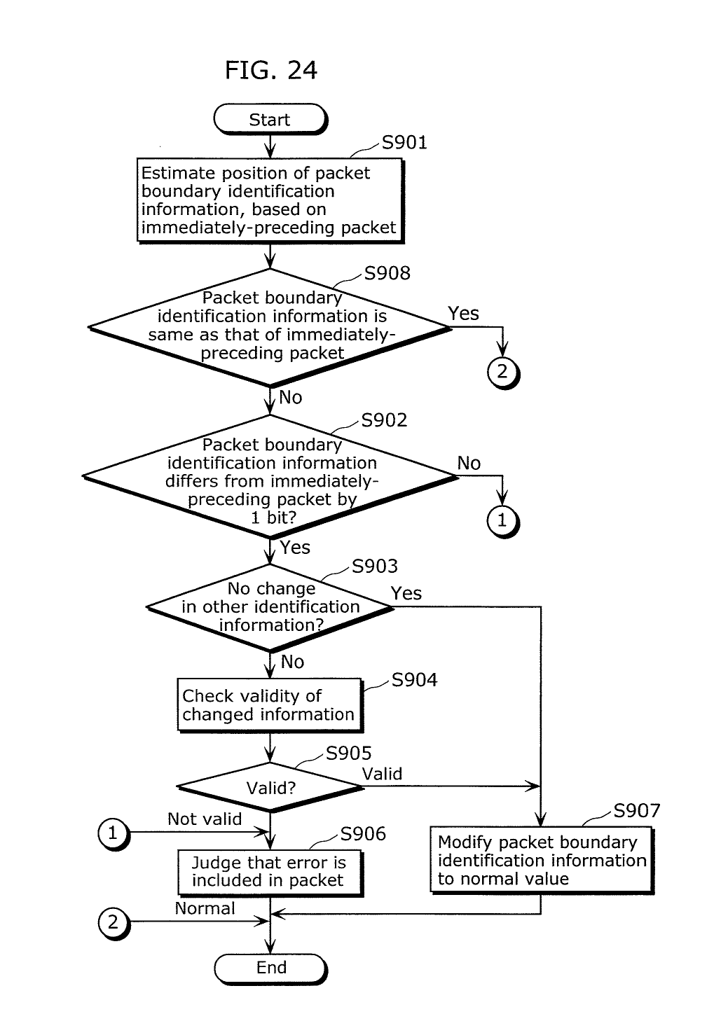

FIG. 24 shows a flowchart of processes performed in the packet information extracting unit 1520 in this embodiment.

Step S901 shows the process for estimating the position of the boundary of current packets as identification information. In the case where a receiving device which receives consecutive data handles only packets having a predetermined size, the receiving device can determine the position indicated by the packet boundary identification information of the currently-received packet, based on the size of the current packet and the position indicated by the packet boundary identification information of the packet received immediately before.

Step S908 shows the process for judging whether or not the packet boundary identification information is normal. The data located at the position estimated in Step S901 is compared with the boundary identification information of the original packet. In the case where the comparison does not indicate a mismatch, a transition to Step S902 is made. In the opposite case where the comparison indicates a match, the received packet is judged to be normal, which completes this judgment process, and then normal packet information is extracted.

Step S902 shows the process for judging the validity of the packet boundary identification information. In the case where the data located at the position estimated in Step S901 is compared with the original packet boundary identification information. In the case where the comparison shows a difference corresponding to 1-bit, a transition to Step S903 is made. In the case where the comparison shows a difference corresponding to 2 or more bits, the received packet is judged as having an error.

Step S903 shows the process for performing a judgment on change in the packet information other than the packet boundary identification information. A transition to Step S904 is made in the case where a change is detected, and in the opposite case where no change is detected, a transition to Step S907 is made.

Step S904 is the process for judging the validity of the packet information other than the changed packet boundary identification information. For example, in the case where the range of the values representing coding schemes is predetermined, it is possible to judge the validity of the packet information other than the changed packet boundary identification information by checking whether or not the value of the packet information other than the changed packet boundary identification information reaches the upper limit of the range. A transition to Step S907 is made in the case where the change is judged to be valid, and in the opposite case where the change is judged to be not valid, the packet information other than the changed packet boundary identification information is judged as having an error (Step S906). A transition to Step S907 is made through Steps S903 and S904 because it is very unlikely that the packet information other than the packet boundary identification information is deformed.

Step S907 is the process for modifying the packet boundary identification information. Step S907 is reached in the case where the packet boundary identification information is changed by only 1 bit, and there is no change in the packet information other than the changed packet boundary identification information or there is a change judged to be valid. Modifying the packet boundary information to have a normal value makes it possible to reconstruct the damaged packet information, judge the packet in which only the packet information is damaged as normal data in the following processes, and prevent stoppage of services such as output of the resulting sound.

After the packet boundary identification information is modified, normal packet information is extracted.

The following describe processes performed in the case where the packet boundary information is deformed by 1 bit.

FIG. 23C shows that the packet boundary information of the packet is deformed by 1 bit. The coding scheme information is also changed from the coding scheme information in FIG. 23B at the same time. However, the change is not data deformation but a normal change made by the transmitting-side apparatus.

When the receiving-side apparatus receives the packet of FIG. 23C, the packet boundary information of the packet is checked in Step S902. Here, the data has been changed by 1 bit from the original value, and thus a transition to Step S903 is made. The coding scheme information in packet information is also changed, the validity of the packet is checked in Step S904. Here, the change in the coding scheme information is judged to be valid, and the header information is reconstructed in Step S907. If the coding scheme information has been changed to an undefined value, the change is judged to be not valid and judged as having an error. There may be cases where deformed coding scheme information is erroneously judged to be valid. In this case, error detection is performed according to one of the first to fourth embodiments other than this embodiment.

FIG. 23D shows the state next to the state shown in FIG. 23C. The packet boundary information has a normal value in FIG. 23D, the receiving-side apparatus can extract the packet information.

As described above, in the case where only the packet boundary information is abnormal because of 1-bit change, the whole packet has been judged as having an error even though the data other than the packet boundary information is normal according to one of the conventional techniques; however, the present invention makes it possible to validate the packet, and output the normal data without stopping the output of the resulting sound.

Here, whether or not the packet boundary identification information is modified is determined depending on whether data deformed by 1 bit is detected in Step S902. It should be noted that even data deformed by 2 or more bits can be modified. However, setting 1 or more bits as a threshold for error judgment increases the possibility that completely damaged data is erroneously reconstructed, and thus increases the possibility that noises are generated.

The above-described embodiments according to the present invention are mere examples, and it should be noted that the present invention is not limited to these embodiments.

Frames having 16 quantized bits are used as examples, but frames having an arbitrary number of bits such as 20, 24 and 32 bits may be used instead.

The sampling frequency of 48 kHz is used as an example in this embodiment, an arbitrary sampling frequency such as 32, 44.1, 96, 88.2, 192, and 176.4 kHz may be used instead.

The 2-channel music data may be music data having an arbitrary channel such as 5.1-channel music data.

Descriptions have been given assuming that the media data is audio data, but other data such as image data may be used instead.

The descriptions have been given assuming that the recording medium on which the media data is recorded is a disc, but the recording medium may be another medium such as an HDD, and a flash memory. In addition, the media data may be distributed through a wired network, a wireless network, and broadcasting.

The above descriptions have been given assuming that the output unit is a speaker, another output device such as headphones may be used instead. The output unit may vary depending on data to be transmitted. In the case of image data, the output unit may be a display device such as an LCD and a CRT.

The above descriptions have been given assuming that the receiving unit and the transmitting unit are paired with each other, but several receiving-side apparatuses and several transmitting-side apparatuses may be connected on a transmission path and communicate with each other in these embodiments, as a matter of course.

Further, the transmitting unit and its internal units, the receiving unit and its internal units, the input control unit, the output control unit can be typically implemented as an LSI which is an integrated circuit. Each of these units may be implemented as a chip, and some or all of these units may be integrated into a chip. For example, it is possible to implement an LSI capable of transmitting and receiving data by integrating the receiving unit and the transmitting unit into a single chip. The integrated circuit is referred to as an LSI here, but an integrated circuit may be referred to as an IC, a VLSI, a system LSI, a super LSI, an ultra LSI, depending on the integration degree.

The integrated circuit is not necessarily implemented as an LSI, and it may be implemented as a dedicated circuit or a general processor. It is also possible to use the Field Programmable Gate Array (FPGA) that enables programming or a reconfigurable processor that can reconfigure the connection or setting of a circuit cell inside the LSI after generating an LSI.

Further, in the case where technique of implementing an integrated circuit that supersedes the LSI is invented along with the development in semiconductor technique or another derivative technique, integration of the function blocks may be implemented using the invented technique, as a matter of course. Bio technique is likely to be adapted.

The transmission path may be a wired line such as a metal line and an optical fiber cable, and a wireless line using, for example, radio waves, infrared rays transmitted through optical transmission lines, and magnetism.

An error code replaces the least significant bit in each channel, but any other replacement scheme for suppressing deterioration in sound quality may be used. Such scheme includes replacing one of L-channel data or R-channel data with error check codes.

A scheme for simply replacing some of the bits representing music data is employed as a scheme for assigning error check codes to the music data, but an arbitrary scheme may be used instead. Such scheme includes compressing music data, assigning and inserting error check codes to the portions corresponding to the differences between the source data and the compressed data without increasing the bandwidth required for transmitting the source data.

The error check codes are even parities, but any codes may be used instead as long as a receiving-side apparatus can detect errors based on the error check codes. Such error check codes includes: odd parities; CRCs and a combination of, horizontal parities and vertical parities obtainable by replacing several bits starting with the least significant bit toward the most significant bit with error check codes; and digital watermarking technology.

The error check codes are calculated for each sampling frequency of the music data in these embodiments. However, error check codes may be calculated: for each unit of temporally-continuous data of different sampling frequencies; and for temporally-discontinuous data of different sampling frequencies obtainable by, for example, extracting alternately-arranged data of different sampling frequencies.

The processing procedures and functional structures are not limited to those taken as examples in these embodiments. For example, the packet information assigning unit next to the coding unit may execute the processing for combining packets with the data of media data and attribute information combined by the packetization unit.

The error control unit is shown as an example of a structural element necessary for achieving the present invention. In the case where no error has occurred, data may be processed and outputted. For example, error check codes embedded in the source data may be removed, and the source data without the error check codes may be transmitted and outputted. In this case, any signal processing scheme may be applicable as long as it is for reducing noises, in addition to the above-described processes performed in the case where an error is included in the data. Another error processing may be performed; such processing includes transmitting an error signal and a stop signal to other apparatus which uses outputted source data.

In the case of media data which does not need to be transmitted in real time, an error state may be recovered according to a scheme of requesting a transmitting-side apparatus to re-transmit the media data, instead of processing the transmitted source data to be outputted in order to prevent noises.

The described packet sizes and block sizes are examples, and other sizes can be applied. A transmission scheme for dynamically changing such sizes instead of using fixed values during transmission on a network can be applied by dynamically changing the packet sizes and block sizes stored in the receiving-side apparatus according to those of the transmitted data.

### INDUSTRIAL APPLICABILITY

The present invention is applicable to detect data damage caused in transmission through networks, and prevent the influence of data damage on a receiving-side system. The present invention is applicable in: transmission between a radio receiving device and an amplifier; transmission between a television receiving tuner, an amplifier, and a display; transmission between a mobile telephone and wireless headphones; a system allowing a receiving-side apparatus to reproduce music data distributed through streaming broadcasting through the Internet and the like or satellite communication; and transmission between a music source in an audio device and an amplifier mounted on a car. The present invention is especially useful for preventing such noises generated in a receiving-side system in an audio device mounted on a car due to data damage because such noises may affect the driver, resulting in exposing the persons in the car to danger.

What is claimed is:

1. A data transmitting apparatus comprising: a transmitting unit which codes unit blocks each of which includes at least one unit of transmission data, and transmits the coded unit blocks to a transmission path; and a receiving unit which receives the coded unit blocks from said transmitting unit through the transmission path, the unit block being a minimum amount of data which is coded at a time, and the unit of transmission data being a minimum amount of data which is transmitted at a time,
wherein said receiving unit includes:
a decoding unit configured to decode the coded unit blocks, and extract the units of transmission data of the respective coded unit blocks;
a check information detecting unit configured to judge whether or not each of the extracted units of transmission data has an error, based on check information usable for error detection, and identify, in the case where a unit of transmission data is judged as having an error, an error unit block including the unit of transmission data judged as having the error; and
an error control unit configured to perform an error processing on the whole identified error unit block.

2. The data transmitting apparatus according to claim 1,
wherein said transmitting unit is further configured to encrypt the unit blocks when coding the unit blocks, and
said decoding unit is further configured to decrypt the encrypted unit blocks received from said transmitting unit.

3. The data transmitting apparatus according to claim 1,
wherein said check information detecting unit is further configured to judge that a unit of transmission data has an error in the case where predetermined check information associated with a current unit of transmission data changes after predetermined check information associated with an immediately-preceding unit of transmission data changes.

4. The data transmitting apparatus according to claim 1,
wherein said transmitting unit includes a check information inserting unit configured to insert check information usable for error detection to each of the unit blocks.

5. The data transmitting apparatus according to claim 4,
wherein said check information inserting unit is further configured, in the case where predetermined attribute information included in the unit block to be coded is changed from immediately-preceding attribute information, to convert a specific portion of the attribute information to check information which is usable for the error detection and can be inversely converted to the specific portion.

6. The data transmitting apparatus according to claim 4,
wherein said check information inserting unit is further configured, in the case where the predetermined attribute information included in the unit block to be coded is changed from the immediately-preceding attribute information, to change at least one character among specific characters of each attribute information in an attribute information sequence, as check information usable for the error detection, in a sequence of error detection performed on the attribute information sequence.

7. The data transmitting apparatus according to claim 4, p1 wherein the unit block includes at least one of the following as the unit of transmission data: (i) at least one unit of frame data; and (ii) attribute information common in units of frame data,
said decoding unit is configured to receive the coded unit blocks sequentially, decode the received unit blocks sequentially, and extract the units of frame data included in the respective unit blocks and the attribute information of the unit blocks sequentially, and
said check information detecting unit is configured to identify the error unit block based on a difference between at least two pieces of the extracted attribute information including the attribute information of the error unit block and the attribute information of a unit block adjacent to the error unit block.

8. The data transmitting apparatus according to claim 1,
wherein at least one of the units of transmission data is a unit of frame data in which an error check code is inserted,
said decoding unit is configured to decode the coded unit blocks, and extract the units of frame data each of which includes an error check code, and
said check information detecting unit is configured to identify the unit blocks based on the error check codes inserted in the respective decoded units of frame data.

9. The data transmitting apparatus according to claim 1,
wherein said transmitting unit is further configured to transmit coded packets including the unit blocks to a transmission path,
said receiving unit is configured to receive the coded packets from said transmitting unit through the transmission path,
said coding unit is configured to receive the coded packets sequentially, decode the received packets sequentially, extract the unit blocks including the units of transmission data included in each of the packets sequentially, and extract the units of transmission data from the unit blocks, and
said check information detecting unit is configured to identify a packet including a unit of transmission data judged as having the error, according to the judgment made based on the check information usable for error detection on the extracted units of transmission data.

10. The data transmitting apparatus according to claim 9,
wherein said check information detecting unit is further configured to judge a unit block to be an error unit block in the case where the unit block includes one or more units of transmission data judged as having the error, and judge a packet to be an error packet in the case where the number of error blocks included in the packet equals to or greater than a predetermined threshold.

11. The data transmitting apparatus according to claim 9,
wherein said receiving unit is further configured, in the case where control information of a received packet includes 1-bit data error, to reconstruct the control information for the packet.

12. The data transmitting apparatus according to claim 1,
wherein the unit of transmission data includes a unit of frame data which is audio data, and
said error control unit is configured to perform one of: a mute processing on sound resulting from audio data corresponding to the whole identified error unit block; and an output processing of outputting sound resulting from a unit of frame data of a non-error frame immediately preceding an error frame, instead of the sound resulting from the audio data.

13. A data transmission system comprising: a transmitting apparatus which codes unit blocks each of which includes at least one unit of transmission data, and transmits the coded unit blocks to a transmission path; and a receiving apparatus which receives the coded unit blocks from the transmitting apparatus through the transmission path, the unit block being a minimum amount of data which is coded at a time, and the unit of transmission data being a minimum amount of data which is transmitted at a time,
wherein said transmitting apparatus includes:
a check information inserting unit configured to insert check information usable for error detection in the unit block, and
a coding unit configured to code the unit block in which the check information is inserted, and transmit the coded unit block to the transmission path, and
wherein said receiving apparatus includes:
a decoding unit configured to decode the coded unit blocks, and extract the units of transmission data of the respective decoded unit blocks;
a check information detecting unit configured to judge whether or not each of the extracted units of transmission data has an error, based on check information usable for error detection, and identify, in the case where a unit of transmission data is judged as having an error, an error unit block including the unit of transmission data judged as having the error; and
an error control unit configured to perform an error processing on the whole identified error unit block.

14. A receiving apparatus which receives coded unit blocks from a transmitting apparatus through a transmission path, said receiving apparatus comprising:
a decoding unit configured to decode the coded unit blocks each of which includes at least one unit of transmission data, and extract the units of transmission data of the respective decoded unit blocks;
a check information detecting unit configured to judge whether or not each of the extracted units of transmission data has an error, based on check information usable for error detection, and identify, in the case where a unit of transmission data is judged as having an error, an error unit block including the unit of transmission data judged as having the error; and
an error control unit configured to perform an error processing on the whole identified error unit block.

15. The receiving apparatus according to claim 14, further comprising
an error control unit configured to:
stop, in the case where the unit of transmission data is judged as having the error, output of the unit of transmission data;
re-start output of a unit of transmission data when units of transmission data are sequentially judged as not having an error for a predetermined period of time after the stoppage of the output of the unit of transmission data;
change the predefined period of time according to a time period from a start of output of a unit of transmission data to a detection of the error; and
vary, depending on the change, the predetermined period of time from a stoppage of output of a unit of transmission data to a re-start of output of a unit of transmission data.

16. A transmitting apparatus which codes unit blocks each of which includes at least one unit of transmission data, and transmits the coded unit blocks to a transmission path, the unit block being a minimum amount of data which is coded at a time, and the unit of transmission data being a minimum amount of data which is transmitted at a time,said transmitting apparatus comprising:
a check information inserting unit configured to insert check information usable for error detection in the unit block; and
a coding unit configured to code the unit block in which the check information is inserted, and transmit the coded unit block to the transmission path.

17. A data transmission method for use with a system comprising: a transmitting apparatus which codes unit blocks each of which includes at least one unit of transmission data, and transmits the coded unit blocks to a transmission path; and a receiving apparatus which receives the coded unit blocks from the transmitting apparatus through the transmission path, the unit block being a minimum amount of data which is coded at a time, and the unit of transmission data being a minimum amount of data which is transmitted at a time,
wherein said data transmitting method performed in the transmitting apparatus includes the steps of: inserting check information usable for error detection in the unit blocks; and
coding the unit block in which the check information is inserted, and transmitting the coded unit block to the transmission path, and
wherein said data transmitting method performed in the receiving apparatus includes the steps of:
decoding the coded unit blocks, and extract units of transmission data of the respective decoded unit blocks;
judging whether or not each of the extracted units of transmission data has an error, based on check information usable for error detection, and identifying, in the case where a unit of transmission data is judged as having an error, an error unit block including the unit of transmission data judged as having the error; and
performing an error processing on the whole identified error unit block.

18. A receiving method for receiving coded unit blocks from a transmitting apparatus through a transmission path, said receiving method comprising:
decoding the coded unit blocks each of which includes at least one unit of transmission data, and extracting the units of transmission data of the respective decoded unit blocks;
judging whether or not each of the extracted units of transmission data has an error, based on check information usable for error detection, and identifying, in the case where a unit of transmission data is judged as having an error, an error unit block including the unit of transmission data judged as having the error; and
performing an error processing on the whole identified error unit block.

19. A transmitting method for coding unit blocks each of which includes at least one unit of transmission data, and transmits the coded unit blocks to a transmission path, the unit block being a minimum amount of data which is coded at a time, and the unit of transmission data being a minimum amount of data which is transmitted at a time,said transmitting method comprising:
inserting check information usable for error detection in the unit blocks; and
coding the unit blocks in which the check information is inserted, and transmitting the coded unit block to the transmission path.

20. A computer-readable program for use with a receiving apparatus which receives coded unit blocks from a transmitting apparatus through a transmission path, said program allowing, when loaded into the apparatus, the apparatus to execute the steps of:
decoding the coded unit blocks each of which includes at least one unit of transmission data, and extracting the units of transmission data of the respective decoded unit blocks;
judging whether or not each of the extracted units of transmission data has an error, based on check information usable for error detection, and identifying, in the case where a unit of transmission data is judged as having an error, an error unit block including the unit of transmission data judged as having the error; and
performing an error processing on the whole identified error unit block.

21. A computer program product for use with a data transmitting apparatus which codes unit blocks each of which includes at least one unit of transmission data and transmits the coded unit blocks to a transmission path, said computer program product allowing, when loaded into the apparatus, the apparatus to execute:
inserting check information usable for error detection in the unit blocks; and
coding the unit blocks in which the check information item is inserted, and transmitting the coded unit blocks to the transmission path.
